(19) United States
(12) Patent Application Publication
(10) Pub. No.: US 2026/0006833 A1
(43) Pub. Date: Jan. 1, 2026

(54) TRANSISTOR METALLIZATION ENDCAP SCALING FOR PERFORMANCE OPTIMIZATION

(71) Applicant: Intel Corporation, Santa Clara, CA (US)

(72) Inventors: Tao Chu, Portland, OR (US); Guowei Xu, Portland, OR (US); Robin Chao, Portland, OR (US); Feng Zhang, Portland, OR (US); Ting-Hsiang Hung, Beaverton, OR (US); Chia-Ching Lin, Portland, OR (US); Yang Zhang, Rio Rancho, NM (US); Kan Zhang, Hillsboro, OR (US); Chun Wing Yeung, Portland, OR (US); Minwoo Jang, Portland, OR (US); Yanbin Luo, Portland, OR (US); Paul Packan, Hillsboro, OR (US); Chung-Hsun Lin, Portland, OR (US); Anand Murthy, Portland, OR (US)

(73) Assignee: Intel Corporation, Santa Clara, CA (US)

(21) Appl. No.: 18/759,205

(22) Filed: Jun. 28, 2024

(51) Int. Cl. H01L 29/417; H01L 27/092; H01L 29/06; H01L 29/423; H01L 29/778; H01L 29/786

(52) U.S. Cl. CPC H10D 30/6729; H10D 30/47; H10D 30/6735; H10D 30/6757; H10D 62/118; H10D 84/85

(57) ABSTRACT

Integrated circuit (IC) devices having transistors with electrodes and/or contacts in close proximity. An IC device includes a transistor structure having a channel between a source and a drain, a gate electrode over the channel region, and contacts on the source and the drain, and the electrode and contacts extend past an edge or sidewall of the channel different distances, that is, with unaligned ends. One or both of the source and drain contacts may extend past the gate electrode. The gate electrode may extend past one or both of the source and drain contacts. The source and drain contacts and the gate electrode may be formed to unaligned dimensions or may be disaligned by trimming.

### BACKGROUND

As transistor dimensions are continually scaled down and integrated circuit (IC) device densities increase, the quantity and magnitude of opportunities for process performance improvements may be reduced. Accordingly, design-technology co-optimization (DTCO) is being relied on more as a significant source of performance improvement. Previously, e.g., in larger devices with larger pitches, some performance effects of scaling were not so significant. In current and forthcoming device generations, device dimensions are so constricted that every nanometer of metallization (e.g., gate electrodes and/or contacting source and drain bodies) will likely impact transistor characteristics in multiple ways.

New techniques and structures are needed to improve the performance of IC devices having tightly constrained contact structures.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a plan view of an integrated circuit (IC) device having unaligned endcaps of gate electrodes and source and drain contacts in adjacent transistor structures, in accordance with some embodiments;

FIGS. 2A, 2B, and 2C illustrate plan and cross-sectional profile views of an IC device having unaligned endcaps of electrodes and contacts, including a wide portion of a semiconductor region in a transistor structure, in accordance with some embodiments;

FIGS. 3A, 3B, and 3C illustrate plan and cross-sectional profile views of an IC device having unaligned endcaps of electrodes and contacts, including an intermediate portion of a semiconductor region in a transistor structure, in accordance with some embodiments;

FIGS. 4A, 4B, and 4C illustrates plan and cross-sectional profile views of an IC device having unaligned endcaps of electrodes and contacts, including a narrow portion of a semiconductor region in a transistor structure, in accordance with some embodiments;

FIG. 5 illustrates a plan view of an IC device having unaligned endcaps of gate electrodes and source and drain contacts in adjacent transistor structures, in accordance with some embodiments;

FIG. 6 is a flow chart of methods for forming a transistor structure with unaligned endcaps of gate electrodes and source and drain contacts, in accordance with some embodiments;

FIG. 7 illustrates a diagram of an example data server machine employing an IC device having a transistor with an unaligned source or drain contact or gate electrode, in accordance with some embodiments; and

FIG. 8 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed to improve performance of integrated circuit (IC) devices having transistors with source and drain contacts in close proximity with gate electrodes and contacts.

Conventional IC devices often have millions or billions of transistors arrayed in thoughtfully and precisely arranged cells. Transistors are carefully aligned, and parallel metallization structures are also aligned, often with metallization structures (for example, gate electrodes and source and drain contacts) extending beyond otherwise necessary dimensions (e.g., contact lengths) to align gate and contact endcaps. This uniformity and alignment may have been to satisfy design requirements (e.g., balancing design and layout demands, minimizing process variation, ensuring proper and sufficient contact and reliability, etc.), but the present disclosure describes structures and techniques that improve device performance by disaligning endcaps of transistor metallization. Unaligned or disaligned ends of transistor gates and source and drain contacts do not align with the other ends on lines parallel to transistor channels. With endcaps not fixed to traditional alignment constraints, transistor electrodes and contacts may be sized as appropriate to maximize performance.

For example, inter-terminal parasitic capacitances can be reduced by decreasing the amount (e.g., area) of transistor metallization adjacent (e.g., parallel and in close proximity) to other transistor metallization. However, reducing electrode and contact metallization may also affect other parameters. For example, reductions in gate dimensions may affect both leakage and drive currents. Scaled down gate dimensions may increase drain-induced barrier lowering (DIBL), resulting in lower threshold voltage (V_{T}) and higher currents. Adjusting gate dimensions may also have effects on threshold voltage V_{T} due to changes to workfunction volumes adjacent a channel region. Shrinking gates or (perhaps more significantly) source and drain contacts may influence external resistance (Rₑₓₜ; for example, contact and interconnect resistances). Current and imminent design-technology co-optimization (DTCO) should include consideration of, and solutions for addressing, these effects.

Metallization structures may be, for example, initially fabricated with unaligned ends, or metallization structures may be fabricated to have aligned endcaps, e.g., conventionally, before one or more of the structures are trimmed to be shorter with unaligned endcaps. Trimming may be by metal gate cuts (or similar etches) between adjacent metallization structures, at least one of which is to be trimmed to disalignment. Metallization structures may be fabricated by any suitable means.

In many embodiments, one or more gate electrodes and/or source or drain contacts in a transistor structure have a reduced size. The reduced dimension (e.g., orthogonal to a channel length) improves device performance by lowering the parasitic capacitance(s) between transistor terminals. Electrodes or contacts may be shortened, and to the desired extent, to tune device performance, for example, to suit a certain application. High-performance (e.g., high-drive) transistors may be tuned to have a lower threshold voltage V_{T} and a lower contact resistance. Other transistors may be tuned to prioritize a lower leakage current (e.g., provided by a higher threshold voltage V_{T} and an acceptably higher contact resistance). In some embodiments, the dimension of a gate electrode is reduced to less than the length of a source or drain contact. The reduced gate electrode dimension may further improve device performance by lowering the threshold voltage V_{T} and increasing drive current, while the longer source and drain contact lengths ensure low contact resistances for conducting the increased drive current. In some embodiments, the length of a source or drain contact is reduced to less than the dimension of a gate contact. A sufficiently long gate electrode may ensure an adequately high threshold voltage V_{T} and correspondingly low leakage current, while a reduced source and drain contact length may further help limit leakage current. In some embodiments, the lengths of source contacts in adjacent transistor structures are approximately equal (e.g., to minimize a consistent gate-source resistance in adjacent transistor structures), and the gate electrode dimension and/or drain contact length are less than corresponding source contact lengths (e.g., to minimize parasitic capacitances).

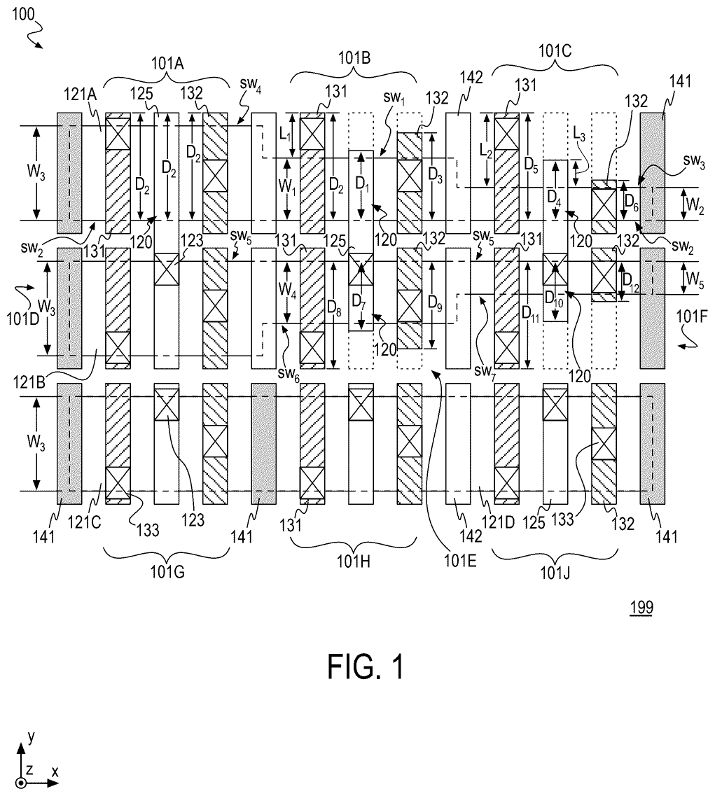

FIG. 1 illustrates a plan view of an IC device 100 having unaligned endcaps of gate electrodes 125 and source and drain contacts 131, 132 in adjacent transistor structures 101, in accordance with some embodiments. Gate electrodes 125 and source and drain contacts 131, 132 are on or over channel regions 120, and may extend over channel regions 120 to different distances beyond an edge or sidewall of channel regions 120. In some transistor structures 101, one or more of electrode 125 and contacts 131, 132 have a reduced dimension (e.g., in the y-direction), for example, less than a dimension of one or more of the others of electrode 125 and contacts 131, 132. The reduced dimension(s) may improve performance of (the corresponding structure 101 and) device 100, e.g., at least by reducing parasitic capacitance(s) between electrode 125 and/or contacts 131, 132.

In the example of FIG. 1, multiple semiconductor regions 121 (e.g., regions 121A, 121B, 121C) provide channel regions 120 for transistor structures 101 (e.g., region 121A for structures 101A, 101B, 101C; region 121B for structures 101D, 101E, 101F; 121C for structure 101G; and region 121D for structures 101H, 101J). Transistor structures 101 may be transistors (e.g., field-effect transistors, FETs) of any suitable structure, and semiconductor regions 121 may have corresponding structure (e.g., fins of semiconductor material in FinFET structures 101). Edges (e.g., sidewalls) of semiconductor regions 121 are generally represented with solid lines. Dashed lines show covered sidewalls of regions 121 (e.g., where covered by electrodes 125; contacts 131, 132; etc.). Dotted lines illustrate where electrodes 125 and contacts 131, 132 might conventionally extend to, e.g., to unnecessarily long distances.

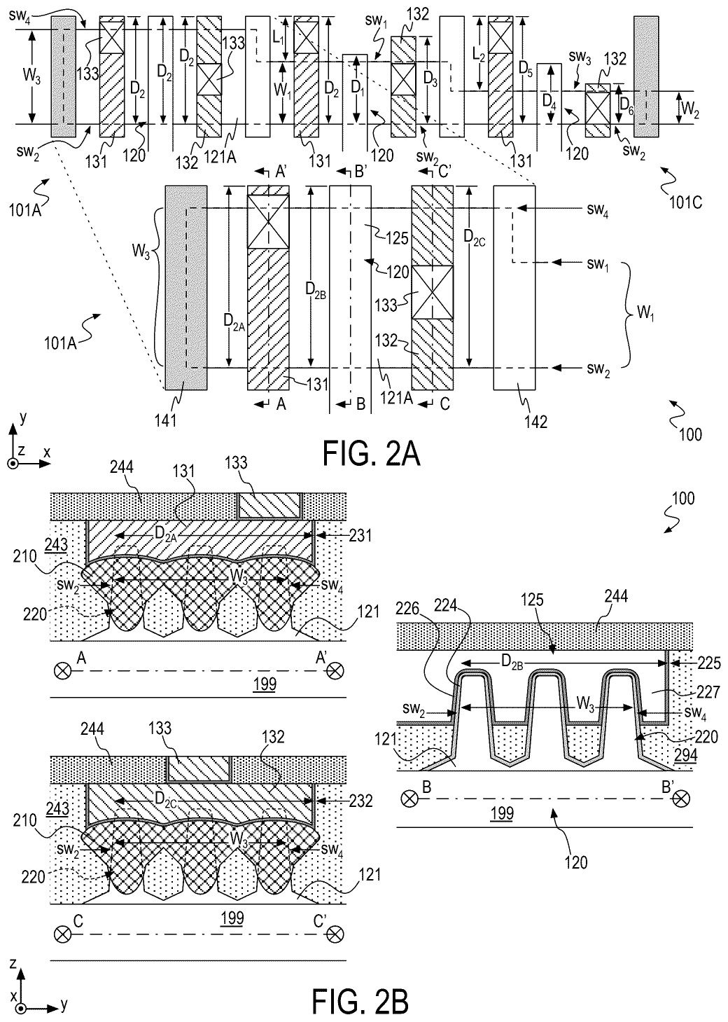

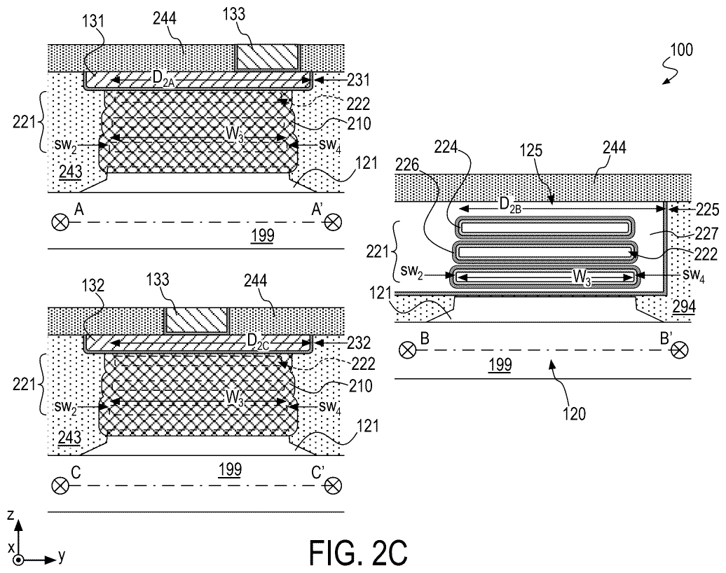

IC device 100 includes multiple transistor structures 101, each with gate electrode 125 for controlling conduction of channel region 120 between source and drain bodies. Channel region 120 extends in the x-direction between source and drain bodies of impurity-doped semiconductor material. Source and drain bodies (under and covered by source and drain contacts 131, 132) are not shown in FIG. 1. (Source and drain bodies are shown and described at FIG. 2A, etc.). Each transistor structure 101 has a gate electrode 125 on a corresponding channel region 120 and between (and mechanically parallel with) a pair of contacts 131, 132. For example, device 100 includes transistor structure 101B with a channel region 120 in semiconductor region 121A. In transistor structure 101B, channel region 120 (and semiconductor region 121A) has a first width W₁ between edges or sidewalls sw₁, sw₂. Of the pair of contacts 131, 132 in each transistor structure 101, one of source and drain contacts 131, 132 is on a source body, and the other of contacts 131, 132 is on a drain body (the source and drain bodies coupled by channel region 120).

Gate electrode 125 is between source and drain bodies (under contacts 131, 132) and on and over channel region 120. Gate electrode 125 includes a conductive (e.g., metal) portion and an insulator (e.g., a gate dielectric) between channel region 120 and the conductive portion, on channel region 120. For example, transistor structures 101 may be metal-oxide-semiconductor (MOS) FETs with electrode 125 including one or more oxides in a gate dielectric on channel region 120, between a metal gate and a semiconductor channel region 120. Gate electrode 125 extends in the y-direction. In transistor structure 101B, electrode 125 extends beyond a first edge or sidewall sw₁ of channel region 120 to a distance D₁ from a second edge or sidewall sw₂, opposite edge or sidewall sw₁.

First and second contacts 131, 132 are each over and in contact with one of a pair of source and drain bodies, e.g., a source or a drain of transistor structure 101B. In many embodiments, although source and drain contacts 131, 132 may have different sizes (e.g., lengths), the associated source and drain bodies are symmetrical in transistor structure 101B and are determined by the electrical connections to transistor structure 101B. For descriptive purposes, e.g., convenience and/or clarity, contacts 131 will be described as being on source bodies, and contacts 132 will be described as being on drain bodies, but structures 101 and contacts 131, 132 may be otherwise configured. Source and drain contacts 131, 132 are metallization structures (e.g., electrodes) on and covering the source and drain bodies of transistor structure 101 coupled by channel region 120. First contact 131 (e.g., on a source of structure 101B) and second contact 132 (e.g., on a drain of structure 101B) both extend in the y-direction. Contact 131 extends beyond sidewall sw₁ to a distance D₂ from sidewall sw₂ of channel region 120. Contact 132 extends beyond sidewall sw₁ to distance D₃ from sidewall sw₂ of channel region 120. Distance D₂ is greater than distance D₃. Distance D₃ is greater than distance D₁.

The shorter distance D₁ for gate electrode 125 (for example, relative to longer distances D₂, D₃ for source and drain contacts 131, 132) corresponds to advantageously lower parasitic capacitances between electrode 125 and contacts 131, 132 and higher operating frequencies of transistor structure 101B and device 100. The reduced distance D₁ for electrode 125 may further improve performance of device 100 by lowering the threshold voltage V_{T} of structure 101B and increasing drive current. The longer distances D₂, D₃ for contacts 131, 132 ensure low contact resistances for conducting the increased drive current. In many embodiments, adjacent transistor structures 101 are coupled to a same interconnect line (e.g., over structures 101 in the positive z-direction and extending in the y-directions) by aligned source contacts 131, e.g., extending to a same distance D₂ from sidewall sw₂ of channel region 120. With contact 131 extending to distance D₂ from sidewall sw₂, distances D₁, D₃ of electrode 125 and contact 132 may be reduced to tune parameters of structure 101B.

Metallization structures 123, 133 such as vias or contacts, coupling transistor structures 101 to interconnect networks are represented by with a boxed ‘X’ over electrodes 125 and contacts 131, 132. Structures 123 couple gate electrodes 125, and structures 133 couple source and drain contacts 131, 132, to interconnect levels (e.g., metallization through dielectric layers) in front- and/or back-side interconnect networks.

Semiconductor regions 121 includes multiple channel regions 120. Region 121A includes region 120 of transistor structure 101B (with width W₁ and sidewalls sw₁, sw₂). Region 121A extends beyond transistor structure 101B and includes channel region 120 (with width W₃ between sidewalls sw₂, sw₄.) in transistor structure 101A, between source and drain bodies (not shown; covered by source and drain contacts 131, 132) in structure 101A. Region 121A extends beyond transistor structure 101B and includes channel region 120 (with width W₂ between sidewalls sw₂, sw₃.) in transistor structure 101C, between source and drain bodies (not shown; covered by source and drain contacts 131, 132) in structure 101C.

Semiconductor regions 121 may each include multiple, distinct semiconductor structures, e.g., multiple parallel fins of a semiconductor material, such as silicon, in FinFETs. Semiconductor regions 121 may be continuous, monolithic semiconductor structures, for example, each a continuous portion of substrate 199 (e.g., having multiple parallel fins, continuous below trench isolation between the fins). Regions 121 may be discontinuous. For example, a region 121 may be a stack of previously continuous nanoribbons interrupted or broken up by source and drain bodies between adjacent transistor structures 101, the previously continuous nanoribbons now nanoribbon segments contiguous (and coupled by) source and drain bodies into a region 121 (e.g., with nanoribbon segments having collinear edges or coplanar sidewalls). Other structures may be utilized. Regions 121 may be isolated from other regions 121 by one or more electrically insulating materials (such as a low-permittivity or “low-K” dielectric material, not shown) between regions 121.

Substrate 199 may include any suitable material or materials. Any suitable semiconductor or other material can be used. Substrate 199 may be any suitable substrate 199, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components (such as regions 121) are also silicon. In some embodiments, a crystalline material of substrate 199 is removed (e.g., by grinding) from a back-side of transistor structures 101 and replaced with an isolation material. Substrate 199 may be a silicon-on-insulator (SOI) substrate. Substrate 199 may also include semiconductor materials, metals, dielectrics, dopants, and other materials commonly found in IC substrates. For example, one or more interconnect networks (not shown) may include metallization through dielectric layers in stacks of interconnect levels on front- and/or back-sides of substrate 199 (e.g., in the positive and/or negative z-directions).

Isolation structures 141 are between adjacent transistor structures 101 and contacts 131, 132 (e.g., through semiconductor regions 121), including between adjacent cells in device 100. Other structures 142 are on (or over) regions 121, between adjacent transistor structures 101 and source and drain contacts 131, 132. Structures 142 may be deployed in or over transition portions of regions 121, e.g., between adjacent transistor structures 101 having channel regions 120 of different widths. In some embodiments, structures 142 are isolation structures 142 through regions 121 and between adjacent transistor structures 101. In some embodiments, structures 142 are electrically floating structures 142 in contact with (but electrically insulated from) regions 120, e.g., high-impedance nodes without a low-impedance path to circuit components (for example, interconnect networks or terminals of structures 101, such as electrodes 125 or contacts 131, 132). In some embodiments, structures 142 are utilized as electrodes 125, e.g., coupled to signals from an interconnect network, in transistor structures 101 between, and series connected with, other structures 101.

Channel region 120 (of both transistor structure 101C and semiconductor region 121A) extends in the x-direction between source and drain bodies under (and covered by) contacts 131, 132. Gate electrode 125 (of transistor structure 101C) is between the source and drain bodies of transistor structure 101C and on channel region 120. Gate electrode 125 extends over channel region 120 in the y-direction. In transistor structure 101C, electrode 125 extends beyond a sidewall sw₃ of channel region 120 to a distance D₄ from sidewall sw₂, opposite sidewall sw₃. Contacts 131, 132 of transistor structure 101C both extend in the y-direction. Contact 131 extends beyond sidewall sw₃ to a distance D₅ from sidewall sw₂. Contact 132 extends beyond sidewall sw₃ to distance D₆ from sidewall sw₂. Distance D₅ is greater than distance D₄. Distance D₄ is greater than distance D₆.

For transistor structure 101C, the shorter distance D₆ for contact 132 (for example, relative to longer distances D₄, D₅ for electrode 125 and contact 131) and distance D₄ for electrode 125 (for example, relative to longer distance D₅ for contact 131) correspond to advantageously lower parasitic capacitances between electrode 125 and contacts 131, 132 and higher operating frequencies of transistor structure 101C and device 100. If desired, a reduced distance D₄ for electrode 125 (for example, relative to longer distance D₅ for contact 131) may lower threshold voltage V_{T} of structure 101C. However, the magnitudes of distance D₄ and length L₃ of electrode 125 beyond sidewall sw₃ may be sufficiently preserved to maintain a sufficiently high threshold voltage V_{T} to support low leakage currents, e.g., for applications prioritizing low shut-off currents. The shorter distance D₆ for contact 132 may correspond to an elevated contact resistance, which may be satisfactory, e.g., in applications prioritizing low shut-off currents.

As with source contact 131 over transistor structure 101B, contact 131 over transistor structure 101C extends to couple with a via beyond an edge (e.g., sidewall sw₁ for transistor structure 101B and sidewall sw₃ for transistor structure 101C) of semiconductor region 121A. For example, contacts 131 of transistor structures 101B, 101C may be coupled to the same interconnect line over transistor structures 101. Distances D₂, D₅ from sidewall sw₂ for contacts 131 of transistor structures 101B, 101C, respectively, are approximately equal. With contacts 131 extending to distance D₂ from sidewall sw₂, distances D₁, D₄ of electrodes 125 and distances D₃, D₆ of contacts 132 may be reduced to tune parameters of structures 101B, 101C.

In embodiments with source contacts 131 in adjacent transistor structures 101 aligned to a same distance D₂, D₅ from sidewall sw₂ of semiconductor region 121A (and channel regions 120), contacts 131 may extend to different lengths (e.g., length L₁, length L₂) beyond sidewalls sw₁, sw₃. For example, contact 131 over transistor structure 101B extends to length L₁ beyond sidewall sw₁ of is greater than length L₂. Contact 131 over transistor structure 101C extends to length L₂ beyond sidewall sw₃. Length L₂ is greater than length L₁. With distances D₂, D₅ being approximately equal, the differences in lengths L₁, L₂ are related to the differences in widths W₁, W₂. Channel region 120 of transistor structure 101B includes width W₁ between sidewalls sw₁, sw₂. Channel region 120 of transistor structure 101C includes width W₂ between sidewalls sw₂, sw₃. Width W₁ is greater than width W₂.

Semiconductor region 121A (in addition to including channel region 120 having width W₁ and sidewalls sw₁, sw₂ in transistor structure 101B and channel region 120 having width W₂ and sidewalls sw₂, sw₃ in structure 101C) extends beyond transistor structure 101B (e.g., in the negative x-direction) and includes channel region 120 in transistor structure 101A. Semiconductor region 121A and channel region 120 have width W₃ between sidewalls sw₂, sw₄ in transistor structure 101A. Semiconductor region 121A includes channel region 120 with width W₁ in transistor structure 101B between channel regions 120 with widths W₃, W₂ in transistor structures 101A, 101C, respectively. Width W₃ of region 121A in transistor structure 101A is greater than width W₁ of region 121A in transistor structure 101B, and width W₁ of region 121A in transistor structure 101B is greater than width W₂ of region 121A in transistor structure 101C. Semiconductor region 121A (and transistor structures 101A, 101B, 101C) are described in greater detail, including in cross-section, at FIGS. 2A-4C.

Channel region 120 (of both transistor structure 101A and semiconductor region 121A) extends in the x-direction between source and drain bodies under (and covered by) contacts 131, 132. Gate electrode 125 (of transistor structure 101A) is between the source and drain bodies of transistor structure 101A and on and over channel region 120. Gate electrode 125 extends over channel region 120 in the y-direction. In transistor structure 101A, electrode 125 extends beyond a sidewall sw₄ of channel region 120 to distance D₂ from sidewall sw₂, opposite sidewall sw₄. Contacts 131, 132 of transistor structure 101A both extend in the y-direction beyond sidewall sw₄ to distance D₂ from sidewall sw₂.

IC device 100 includes multiple semiconductor regions 121, which may be doped similarly or in a complementary manner. Transistor structures 101 of adjacent semiconductor regions 121 may be of the same or complementary conductivity types, e.g., n- and p-type MOSFETs (NMOS and PMOS FETs). Adjacent transistor structures 101 (for example, complementary structures 101) on adjacent regions 121 may be paired, e.g., coupled by shared gate electrode 125, in a complementary MOS (CMOS) device. Paired, complementary structures 101 may be similarly tuned (e.g., having similar dimensions for respective electrodes 125 and for respective contacts 131, 132) for similar performance, e.g., in an application prioritizing parameters, such as high-drive current or low-leakage current.

In the example of FIG. 1, transistor structure 101B of semiconductor region 121A and transistor structure 101E of semiconductor region 121B are of complementary conductivity types. For example, structures 101A, 101B, 101C may be PMOS FETs, and structures 101D, 101E, 101F may be NMOS FETs (or vice versa). In some such embodiments, transistor structures 101A, 101B, 101C include source and drain bodies (e.g., of epitaxial semiconductor material under respective contacts 131, 132) doped with p-type impurities (such as boron or gallium), and transistor structures 101D, 101E, 101F include source and drain bodies (e.g., of epitaxial semiconductor material under respective contacts 131, 132) doped with n-type impurities (such as phosphorous or arsenic). Any of regions 121A, 121B, 121C may support transistor structures 101 of either conductivity type.

Semiconductor region 121B and transistor structure 101E include channel region 120. In structure 101E, regions 120, 121B have width W₄ between edges or sidewalls sw₅, sw₆. In transistor structure 101E, regions 120, 121B extend in the x-direction between source and drain bodies under (and covered by) contacts 131, 132. Transistor structures 101B, 101E share gate electrode 125, which spans regions 120, 121A, 121B and adjacent sidewalls sw₂, sw₅. Gate electrode 125 is parallel with and between the source and drain bodies of structure 101E and on channel region 120. Gate electrode 125 extends over channel regions 120 in the y-directions. In structure 101E, electrode 125 extends in the negative y-direction beyond a sidewall sw₆ of channel region 120 to a distance D₇ from sidewall sw₅, opposite sidewall sw₆. In structure 101B, electrode 125 extends in the positive y-direction beyond sidewall sw₁ of that channel region 120 (of structure 101B) to distance D₁ from sidewall sw₂. Contacts 131, 132 of transistor structure 101E both extend in the y-direction. Contact 131 extends beyond sidewall sw₆ to a distance D₈ from sidewall sw₅. Contact 132 extends beyond sidewall sw₆ to distance D₉ from sidewall sw₅. Distance D₈ is greater than distance D₉. Distance Do is greater than distance D₇.

Transistor structures 101B, 101E have a shared input at gate electrode 125 and may be paired or tuned together (e.g., with similar or the same dimensions for corresponding electrodes 125 and contacts 131, 132), for example, to optimize certain parameters for a particular application. In some embodiments, structures 101B, 101E are symmetric about a line of reflection between structures 101B, 101E (e.g., between semiconductor regions 121A, 121B) with widths W₁, W₄ approximately equal, distances D₁, D₇ approximately equal, distances D₂, D₈ approximately equal, and distances D₃, D₉ approximately equal.

Semiconductor region 121B extends beyond transistor structure 101E and includes channel region 120 between source and drain bodies (not shown) in transistor structure 101F. Semiconductor region 121B and transistor structure 101F both include this channel region 120. In structure 101F, regions 120, 121B have width W₅ between sidewalls sw₅, sw₇. Width W₄ of region 121B (and structure 101E) between edges or sidewalls sw₅, sw₆ is greater than width W₅ of region 121B (and structure 101F) between sidewalls sw₅, sw₇. In transistor structure 101F, regions 120, 121B extend in the x-direction between source and drain bodies under (and covered by) contacts 131, 132. Transistor structures 101C, 101F share gate electrode 125, which spans regions 120, 121A, 121B and adjacent sidewalls sw₂, sw₅. Gate electrode 125 is parallel with and between the source and drain bodies of structure 101F and on channel region 120. Gate electrode 125 extends over channel regions 120 in structures 101C, 101F in the y-directions. In structure 101F, electrode 125 extends in the negative y-direction beyond sidewall sw₇ to a distance D₁₀ from sidewall sw₅. In structure 101C, electrode 125 extends in the positive y-direction beyond sidewall sw₃ of that channel region 120 (of structure 101C) to distance D₄ from sidewall sw₂. Contacts 131, 132 of transistor structure 101F both extend in the y-direction. Contact 131 extends beyond sidewall sw₇ to a distance D₁₁ from sidewall sw₅. Contact 132 extends beyond sidewall sw₇ to distance D₁₂ from sidewall sw₅. Distance D₁₁ is greater than distance D₁₀. Distance D₁₀ is greater than distance D₁₂.

Transistor structures 101C, 101F have a shared input at gate electrode 125 and may have similar or the same dimensions for corresponding electrodes 125 and contacts 131, 132. In some embodiments, structures 101C, 101F are symmetric about a line of reflection between structures 101C, 101F (e.g., between semiconductor regions 121A, 121B) with widths W₂, W₅ approximately equal, distances D₄, D₁₀ approximately equal, distances D₅, D₁₁ approximately equal, and distances D₆, D₁₂ approximately equal.

FIGS. 2A, 2B, and 2C illustrate plan and cross-sectional profile views of an IC device 100 having unaligned endcaps of electrodes 125 and contacts 131, 132, including a wide portion of semiconductor region 121A in transistor structure 101A, in accordance with some embodiments. FIGS. 2A-2C show additional detail of transistor structure 101A (e.g., as described at FIG. 1), including various embodiments of semiconductor region 121A. FIG. 2A illustrates a plan view of semiconductor region 121A in device 100, including a magnified view of transistor structure 101A having the portion of semiconductor region 121A with wide width W₃. The plan view of FIG. 2A shows the orientation of the cross-sectional views A-A′, B-B′, and C-C′ of FIGS. 2B and 2C. FIG. 2A also illustrates structures 141, 142 to either side of channel region 120 and contacts 131, 132 in structure 101A, including structure 142 over a transition portion of semiconductor region 121A between widths W₃, W₁.

Semiconductor region 121A and channel region 120 have width W₃ between sidewalls sw₂, sw₄ in transistor structure 101A. Width W₃ of region 121A in transistor structure 101A is greater than width W₁ of region 121A in transistor structure 101B. Channel region 120 (of both transistor structure 101A and semiconductor region 121A) extends in the x-direction between source and drain bodies 210 under contacts 131, 132. Gate electrode 125 is between the source and drain bodies 210 of transistor structure 101A and on and over channel region 120. Gate electrode 125 extends over channel region 120 in the y-direction. Electrode 125 extends beyond a sidewall sw₄ of channel region 120 to distance D₂ from sidewall sw₂. Contacts 131, 132 both extend in the y-direction beyond sidewall sw₄ to distance D₂ from sidewall sw₂. Distance D₂ from sidewall sw₂ in transistor structure 101A is equal to each of distance D₂ from sidewall sw₂ in transistor structure 101B and distance D₅ from sidewall sw₂ in transistor structure 101C. In the magnified portion of FIG. 2A, electrode 125 and contacts 131, 132 extend to distinctly labeled distances D_{2A}, D_{2B}, D_{2C} from sidewall sw₂. In some embodiments, some or all of distances D_{2A}, D_{2B}, D_{2C} are shorter or longer than the others of distances D_{2A}, D_{2B}, D_{2C}. In some embodiments, some or all of distances D_{2A}, D_{2B}, D_{2C} are shorter or longer than distance D₂ from sidewall sw₂ in transistor structure 101B and/or distance D₅ from sidewall sw₂ in transistor structure 101C.

FIG. 2B shows cross-sectional profile views of transistor structure 101A, including gate electrode 125 on channel region 120 and contacts 131, 132 on source and drain bodies 210. View A-A′ illustrates source contact 131 on source body 210. View B-B′ shows gate electrode 125 on channel region 120. View C-C′ illustrates drain contact 132 on drain body 210. In the embodiments of FIG. 2B, transistor structure 101A, channel region 120, and semiconductor region 121A include a group of multiple (e.g., three) semiconductor fins 220 in width W₃. Channel region 120 includes at least the portions of fins 220 through which current may conduct between source and drain bodies 210, e.g., as controlled by a signal or bias on gate electrode 125. Fins 220 may be of the same material as substrate 199, for example, silicon or another semiconductor material.

Sidewalls sw₂, sw₄ of regions 120, 121A in transistor structure 101A are sidewalls sw₂, sw₄ of semiconductor fins 220. Width W₃ of region 121A in transistor structure 101A is greater than width W₁ of region 121A in transistor structure 101B (e.g., because width W₃ of regions 120, 121A in structure 101A includes three semiconductor fins 220, and width W₁ of regions 120, 121A in structure 101B includes two semiconductor fins 220).

View A-A′ of FIG. 2B shows source contact 131 on source body 210. In many embodiments, body 210 includes an impurity-doped semiconductor material (such as silicon, silicon germanium, etc., doped with phosphorous, arsenic, etc., in NMOS structures 101A or boron, gallium, etc., in PMOS structures 101A). In many embodiments, body 210 is a crystalline body 210, for example, formed epitaxially from ends of channel region 120. In some such embodiments, body 210 is a merged body 210, for example, formed by joined bodies on the ends of multiple semiconductor fins 220. Body 210 may be a faceted crystalline body 210. Body 210 may be etched down, e.g., by a contact etch, to have a rounded upper surface with a lowest height in the plane of view A-A′. Body 210 may include a metal (e.g., in a metal-semiconductor alloy) in an interface portion on contact 131.

Body 210 may be in (e.g., formed in) a trench etched down into fins 220 of semiconductor region 121. Dashed lines show where borders or edges (e.g., sidewalls and upper surfaces) of fins 220 would project into the viewing plane of view A-A′. Semiconductor region 121 is shown as spreading to a wider base below each fin 220 and over substrate 199. In some embodiments, semiconductor regions 121 are integral with substrate 199 (e.g., of the same material as, and seamless with, substrate 199). In some embodiments, semiconductor regions 121 do not extend substantially below channel regions 120 (e.g., following a grinding down of a backside of substrate 199 and fins 220).

Contact 131 is over and in contact with source body 210, coupling transistor structure 101A (e.g., at body 210) to an interconnect network (e.g., through structure 133). Contact 131 may include multiple materials, for example, a conformal liner metal (on body 210 and isolation material 243) and a bulk or fill metal within the liner metal. Contact 131 extends in the y-direction to sidewall 231 (of contact 131) beyond sidewall sw₄ (of region 120) to distance D_{2A} (greater than width W₃) from sidewall sw₂. Width W₃ of region 120 is between sidewalls sw₄, sw₂. Contact 131 is longer than distance D_{2A}, which is greater than width W₃ and provides a sufficient contact area on body 210.

Metallization structure 133 is a via or contact on source contact 131 and couples transistor structure 101 to an interconnect network. Structure 133 extends through isolation layer 244, which includes an electrically insulating material, such as a low-K dielectric material.

Isolation material 243 is on body 210 and contact 131. Material 243 is an electrically insulating material, such as a low-K dielectric material. Body 210 and contact 131 may be in a trench (e.g., cut into semiconductor region 121A), extending in the y-directions, and insulating material 243 may fill the trench, isolating adjacent structures.

View B-B′ of FIG. 2B illustrates gate electrode 125 on channel region 120, over fins 220 and in and over isolation material 294 over substrate 199. Gate electrode 125 extends in the y-direction to sidewall 225 (of electrode 125) beyond sidewall sw₄ (of region 120) to distance D_{2B} (greater than width W₃) from sidewall sw₂. Gate electrode 125 includes a conductive portion (e.g., metals 226, 227) and an insulator 224 (e.g., a gate dielectric) on channel region 120, between channel region 120 and the conductive portion. Insulator 224 may be conformally over region 120, e.g., fins 220, and gate metal 226 may be conformally over insulator 224. Electrode 125 may include one or more metals 226, 227, for example, a fill metal 227 within a liner metal 226 on gate insulator 224. Each of metals 226, 227 may include one or more constituent metals, e.g., in distinct layers. One or more of metals 226, 227 may be workfunction metals 226, 227, for example, to set a threshold voltage V_{T} of transistor structures 101. Electrode 125 may include multiple liner metals 226, e.g., different liner metals 226 over channel regions 120 in complementary transistor structures 101. Workfunction metals 226 in an NMOS structure 101 may include hafnium, zirconium, titanium, tantalum, aluminum, alloys of these metals, and carbides of these metals such as hafnium carbide, zirconium carbide, titanium carbide, tantalum carbide, etc., and nitrides, such as tantalum nitride, titanium nitride, etc. Workfunction metals 226 in a PMOS structure 101 may include a material such as, but not limited to, ruthenium, palladium, platinum, cobalt, nickel, tungsten, molybdenum, ruthenium, and associated nitrides or carbides of tungsten, ruthenium or molybdenum. Other materials (e.g., metals, workfunction or otherwise) may be deployed.

In addition to the quality (e.g., composition, etc.) of workfunction metals 226, 227, threshold voltages V_{T} of transistor structures 101 may depend on the quantity of workfunction metals 226, 227 adjacent channel regions 120 (e.g., the volume and distribution of metals 226, 227 in electrodes 125). Different dimensions (e.g., distances D₁, D₂, D₄; lengths L₁, L₂) of electrodes 125 may affect threshold voltages V_{T} and performances of transistor structures 101 accordingly.

Gate insulator 224 provides electrical insulation between channel region 120 and gate metals 226 or 227. Insulator 224 may include one or more layers, for example, of a native oxide or passivation layer on channel region 120 and a high-K layer over the passivation layer. Insulator 224 may be of any suitable material(s). The one or more layers may include a silicon oxide, silicon dioxide (SiO₂), a silicon oxynitride, etc. Advantageously, gate insulator 224 includes a high-K dielectric (for example, having a dielectric constant over 6). A high-K dielectric material may include one or more of various elements, such as hafnium, silicon, oxygen, titanium, tantalum, lanthanum, aluminum, zirconium, barium, strontium, yttrium, lead, scandium, niobium, and zinc. Gate insulator 224 may include a dopant, e.g., for elevated permittivity. Examples of high-K materials that may be used in insulator 224 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, etc.

Gate electrode 125 is coupled by a metallization structure (e.g., as structure 123 is described at FIG. 1) through layer 244, similar to metallization structures 133 on contacts 131, 132. Isolation layer 244 may be distinct (e.g., separated) from layer 244 on contacts 131, 132. Isolation layer 244 may have a composition different from (or the same as) layer 244 on contacts 131, 132.

Isolation material 294 is over substrate 199 and fins 220. Electrode 125 may be in material 294 (e.g., surrounded by material 294 on multiple sides). Material 294 is an electrically insulating material, such as a low-K dielectric material.

View C-C′ of FIG. 2B shows drain contact 132 on drain body 210. Contact 132 is similar to contact 131, though contact 132 couples structure 101A at a different body 210 to the interconnect network through a different structure 133. As previously described, source and drain bodies 210 in a given structure 101 may be virtually identical (e.g., symmetric in structures 101) but for the electrical connections to bodies 210 (e.g., different structures 133 coupling, for example, a source body 210 to a power rail and a drain body 210 to a signal output). One of source and drain contacts 131, 132 is on a source body 210, and the other of contacts 131, 132 is on a drain body 210. In the example of FIGS. 2A-2C, contact 132 extends in the y-direction to sidewall 232 beyond sidewall sw₄ to distance D_{2C} from sidewall sw₂ equal to distance D_{2A} to sidewall 231 of contact 131.

Isolation layer 244 may be distinct (e.g., separated) from layer 244 on contact 131 and electrode 125.

FIG. 2C shows cross-sectional profile views of transistor structure 101A, including gate electrode 125 on channel region 120 and contacts 131, 132 on source and drain bodies 210. View A-A′ shows source contact 131 on source body 210. View B-B′ shows gate electrode 125 on channel region 120. View C-C′ shows drain contact 132 on drain body 210. In the embodiments of FIG. 2C, transistor structure 101A, channel region 120, and semiconductor region 121A include a group (e.g., stack 221) of multiple (e.g., three) semiconductor nanoribbons 222 in width W₃. In many embodiments, nanoribbons 222 are of the same material as substrate 199, for example, silicon or another semiconductor material.

Sidewalls sw₂, sw₄ of regions 120, 121A in transistor structure 101A are sidewalls sw₂, sw₄ of nanoribbons 222. Width W₃ of region 121A in transistor structure 101A is greater than width W₁ of region 121A in transistor structure 101B (e.g., because regions 120, 121A in structure 101A have wider width W₃ of semiconductor nanoribbons 222 than the narrower width W₁ of semiconductor nanoribbons 222 of regions 120, 121A in structure 101B). Width W₃ (and widths W₁, W₂, etc.) of nanoribbons 222 may be any suitable width, and nanoribbons 222 may be nanowires or nanosheets.

View A-A′ of FIG. 2C shows source contact 131 on source body 210. Body 210 may be much as previously described (e.g., at FIG. 2B), for example, including an impurity-doped semiconductor material. Notably, body 210 may be a merged body 210, formed by joined bodies on the ends of multiple semiconductor nanoribbons 222 in stack 221. Dashed lines show where borders or edges (e.g., sidewalls and upper and lower surfaces) of nanoribbons 222 would project into the viewing plane of view A-A′.

Semiconductor region 121 is shown as having a wider base (e.g., a subfin) below each stack 221 of nanoribbons 222 and over substrate 199. In some embodiments, semiconductor regions 121 are integral with substrate 199 (e.g., of the same material as, and seamless with, substrate 199). In some embodiments, semiconductor regions 121 consist only of nanoribbons 222 (e.g., following a grinding down of a backside of substrate 199 and a subfin under nanoribbons 222). In some embodiments, stack 221 and nanoribbons 222 of semiconductor region 121 have a shared axis (e.g., a centerline plane), for example, rather than sharing an edge or sidewall sw₂.

View B-B′ of FIG. 2C illustrates gate electrode 125 on channel region 120, over and around nanoribbons 222 and in and over isolation material 294 over substrate 199. Gate electrode 125 extends in the y-direction to sidewall 225 (of electrode 125) beyond sidewall sw₄ (of region 120) to distance D_{2B} (greater than width W₃) from sidewall sw₂. Gate insulator 224 may be conformally over region 120, e.g., over and on nanoribbons 222, and gate metal 226 may be conformally over insulator 224.

View C-C′ of FIG. 2C shows drain contact 132 on drain body 210, similar to contact 131, though coupled to structure 101A at a different body 210 to the interconnect network through a different structure 133. As in the example of FIGS. 2A and 2B, contact 132 extends in the y-direction to sidewall 232 beyond sidewall sw₄ to distance D_{2C} from sidewall sw₂ equal to distance D_{2A} to sidewall 231 of contact 131.

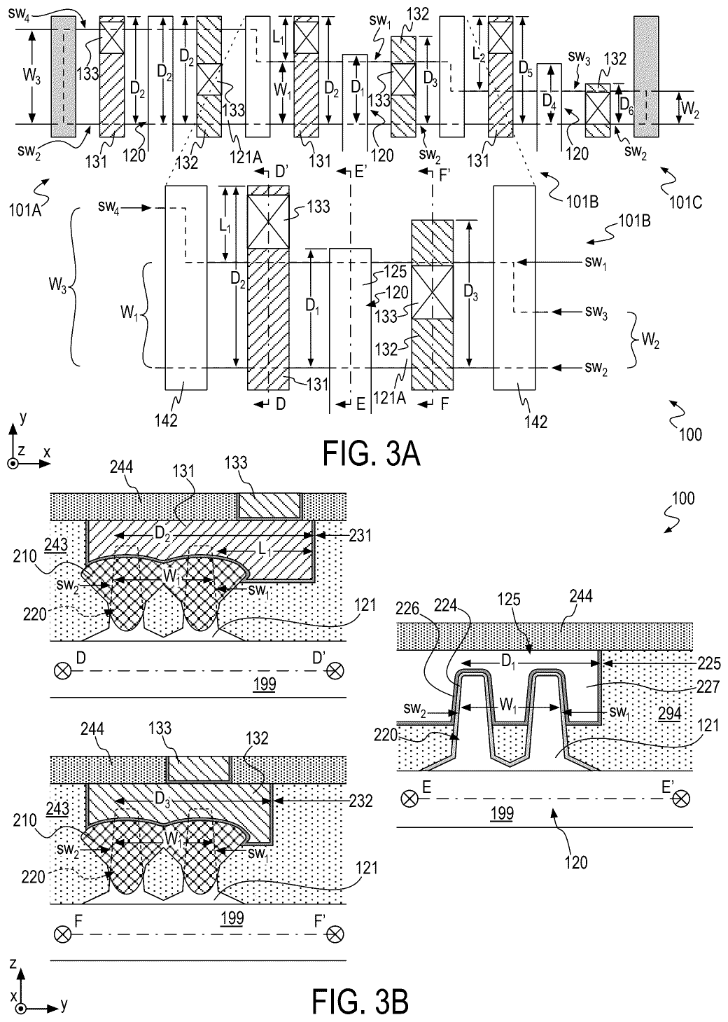

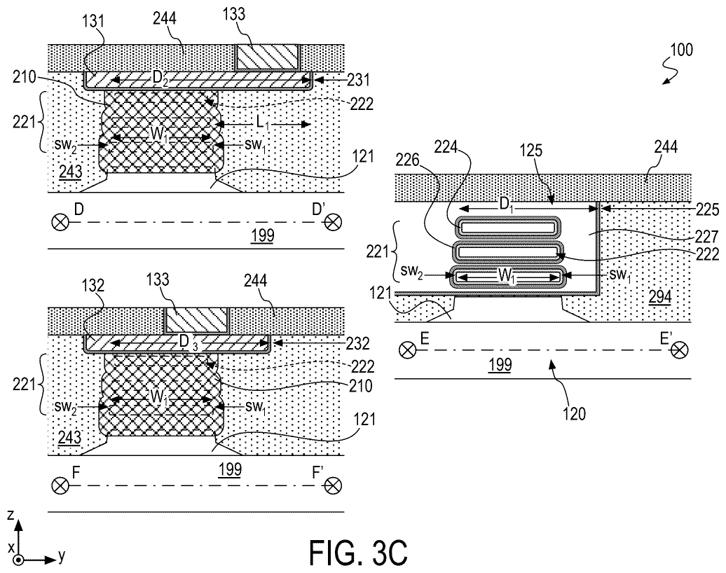

FIGS. 3A, 3B, and 3C illustrate plan and cross-sectional profile views of an IC device 100 having unaligned endcaps of electrodes 125 and contacts 131, 132, including an intermediate portion of semiconductor region 121A in transistor structure 101B, in accordance with some embodiments. FIGS. 3A-3C show additional detail of transistor structure 101B (e.g., as described at FIG. 1), including various embodiments of semiconductor region 121A. FIG. 3A illustrates a plan view of semiconductor region 121A in device 100, including a magnified view of transistor structure 101B having the portion of semiconductor region 121A with intermediate width W₁. The plan view of FIG. 3A shows the orientation of the cross-sectional views D-D′, E-E′, and F-F′ of FIGS. 3B and 3C. FIG. 3A also illustrates structures 142 to either side of channel region 120 and contacts 131, 132 in structure 101B, including structures 142 over transition portions of semiconductor region 121A, between widths W₃, W₁ and between widths W₁, W₂.

Semiconductor region 121A and channel region 120 have width W₁ between sidewalls sw₂, sw₁ in transistor structure 101B. Width W₁ of region 121A in transistor structure 101B is greater than width W₂ of region 121A in transistor structure 101C and less than width W₃ of region 121A in transistor structure 101A. Channel region 120 (of both transistor structure 101B and semiconductor region 121A) extends in the x-direction between source and drain bodies 210 under contacts 131, 132. Gate electrode 125 is between the source and drain bodies 210 of transistor structure 101B and on and over channel region 120. Gate electrode 125 extends over channel region 120 in the y-direction. Electrode 125 extends beyond a sidewall sw₁ of channel region 120 to distance D₁ from sidewall sw₂. Contacts 131, 132 extend in the y-direction beyond sidewall sw₁ to distances D₂, D₃, respectively, from sidewall sw₂. Distance D₂ from sidewall sw₂ in transistor structure 101B is equal to each of distances D₂ from sidewall sw₂ in transistor structure 101A and distance D₅ from sidewall sw₂ in transistor structure 101C. Notably, distance D₂ is greater than distance D₃, and distance D₃ is greater than distance D₁.

FIG. 3B shows cross-sectional profile views of transistor structure 101B, including gate electrode 125 on channel region 120 and contacts 131, 132 on source and drain bodies 210. View D-D′ illustrates source contact 131 on source body 210. View E-E′ shows gate electrode 125 on channel region 120. View F-F′ illustrates drain contact 132 on drain body 210. In the embodiments of FIG. 3B, transistor structure 101B, channel region 120, and semiconductor region 121A include a group of multiple (e.g., two) semiconductor fins 220 in width W₁.

Sidewalls sw₂, sw₁ of regions 120, 121A in transistor structure 101B are sidewalls sw₂, sw₁ of semiconductor fins 220. Width W₁ of region 121A in transistor structure 101B is greater than width W₂ of region 121A in transistor structure 101C (e.g., because width W₁ of regions 120, 121A in structure 101B includes two semiconductor fins 220, and width W₂ of regions 120, 121A in structure 101C includes a single semiconductor fin 220).

View D-D′ of FIG. 3B shows source contact 131 on source body 210. In the example of transistor structure 101B and FIGS. 3A-3C, contact 131 extends in the y-direction to sidewall 231 beyond sidewall sw₁ to distance D₂ from sidewall sw₂ greater than both distance D₁ to sidewall 225 of electrode 125 and distance D₃ to sidewall 232 of contact 132.

Contact 131 of transistor structure 101B extends to the same distance D₂ (or distance D_{2A}; between sidewalls sw₂, 231 and beyond sidewall sw₁) as contact 131 of transistor structure 101A, but with narrower width W₁ (relative to width W₃ of structure 101A) and longer length L₁ (beyond sidewall sw₁), contact 131 provides an additional contact area on body 210 (relative to structure 101A) below an upper surface of body 210, around to a side of body 210.

View E-E′ of FIG. 3B illustrates gate electrode 125 on channel region 120, over fins 220 and in and over isolation material 294 over substrate 199. Gate electrode 125 extends in the y-direction to sidewall 225 (of electrode 125) beyond sidewall sw₁ (of region 120) to distance D₁ (greater than width W₁) from sidewall sw₂.

The reduced distance D₁ (e.g., relative to distances D₂, D₃ of contacts 131, 132 in transistor structure 101B) may improve the device performance of transistor structure 101B by reducing the parasitic capacitances between transistor structure 101B terminals. The reduced distance D₁ (e.g., relative to distance D₂ of electrode 125 in transistor structure 101A) may affect the performance of transistor structure 101B by shifting threshold voltage V_{T} of structure 101B due to the different volume and distribution of metals 226, 227 in electrodes 125.

View F-F′ of FIG. 3B shows drain contact 132 on drain body 210. In the example of transistor structure 101B and FIGS. 3A-3C, contact 132 extends in the y-direction to sidewall 232 beyond sidewall sw₁ to distance D₃ from sidewall sw₂ greater than distance D₁ to sidewall 225 of electrode 125 and less than distance D₂ to sidewall 231 of contact 131.

Contact 132 of transistor structure 101B extends to sufficient distance D₃ (e.g., beyond sidewall sw₁ and greater than width W₁) to provide additional contact area on body 210 (relative to contact 132 of structure 101A, which is over channel region 120 with width W₃ including three fins 220) below an upper surface of body 210, around to a side of body 210.

The reduced distance D₃ (e.g., relative to distance D₂ of contact 131 in transistor structure 101B and distance D₂ of contact 132 in transistor structure 101A) may improve the device performance of transistor structure 101B by reducing the parasitic capacitances between transistor structure 101B terminals.

FIG. 3C shows cross-sectional profile views of transistor structure 101B, including gate electrode 125 on channel region 120 and contacts 131, 132 on source and drain bodies 210. View D-D′ shows source contact 131 on source body 210. View E-E′ shows gate electrode 125 on channel region 120. View F-F′ shows drain contact 132 on drain body 210. In the embodiments of FIG. 3C, transistor structure 101B, channel region 120, and semiconductor region 121A include a group (e.g., stack 221) of multiple semiconductor nanoribbons 222 in width W₁.

Sidewalls sw₂, sw₁ of regions 120, 121A in transistor structure 101B are sidewalls sw₂, sw₁ of nanoribbons 222. Width W₁ of region 121A in transistor structure 101B is greater than width W₂ of region 121A in transistor structure 101C (e.g., because regions 120, 121A in structure 101B have wider width W₁ of semiconductor nanoribbons 222 than the narrower width W₂ of nanoribbons 222 of regions 120, 121A in structure 101C).

View D-D′ of FIG. 3C shows source contact 131 on source body 210. In the example of transistor structure 101B and FIGS. 3A-3C, contact 131 extends in the y-direction to sidewall 231 beyond sidewall sw₁ to distance D₂ from sidewall sw₂ greater than both distance D₁ to sidewall 225 of electrode 125 and distance D₃ to sidewall 232 of contact 132.

Contact 131 of transistor structure 101B extends to the same distance D₂ (or distance D_{2A}; between sidewalls sw₂, 231 and beyond sidewall sw₁) as contact 131 of transistor structure 101A, but with narrower width W₁ (relative to width W₃ of structure 101A) and longer length L₁ (beyond sidewall sw₁).

View E-E′ of FIG. 3C illustrates gate electrode 125 on channel region 120, over and around nanoribbons 222 and in and over isolation material 294 over substrate 199. Gate electrode 125 extends in the y-direction to sidewall 225 (of electrode 125) beyond sidewall sw₁ (of region 120) to distance D₁ (greater than width W₁) from sidewall sw₂.

The reduced distance D₁ (e.g., relative to distances D₂, D₃ of contacts 131, 132 in transistor structure 101B) may improve the device performance of transistor structure 101B by reducing the parasitic capacitances between transistor structure 101B terminals. The reduced distance D₁ (e.g., relative to distance D₂ of electrode 125 in transistor structure 101A) may affect the performance of transistor structure 101B by shifting threshold voltage V_{T} of structure 101B due to DIBL and/or the different volume and distribution of metals 226, 227 in electrodes 125.

View F-F′ of FIG. 3C shows drain contact 132 on drain body 210. In the example of transistor structure 101B and FIGS. 3A-3C, contact 132 extends in the y-direction to sidewall 232 beyond sidewall sw₁ to distance D₃ from sidewall sw₂ greater than distance D₁ to sidewall 225 of electrode 125 and less than distance D₂ to sidewall 231 of contact 131.

Contact 132 of transistor structure 101B extends to distance D₃ (e.g., beyond sidewall sw₁ and greater than width W₁) to provide sufficient contact area on body 210. The reduced distance D₃ (e.g., relative to distance D₂ of contact 131 in transistor structure 101B and distance D₂ of contact 132 in transistor structure 101A) may improve the device performance of transistor structure 101B by reducing the parasitic capacitances between transistor structure 101B terminals.

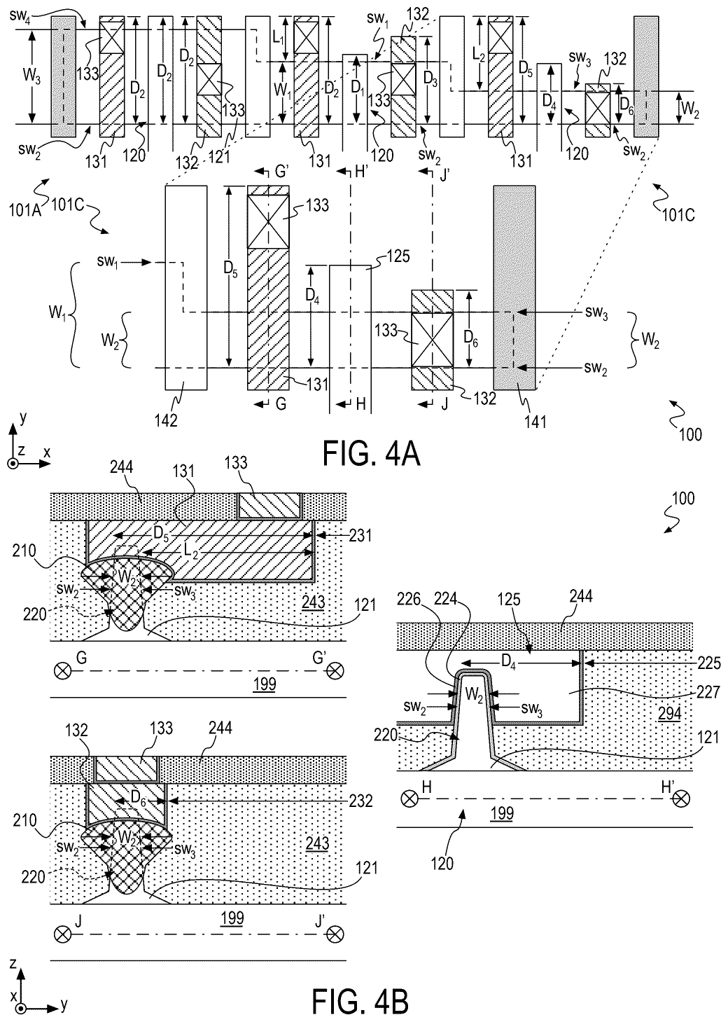

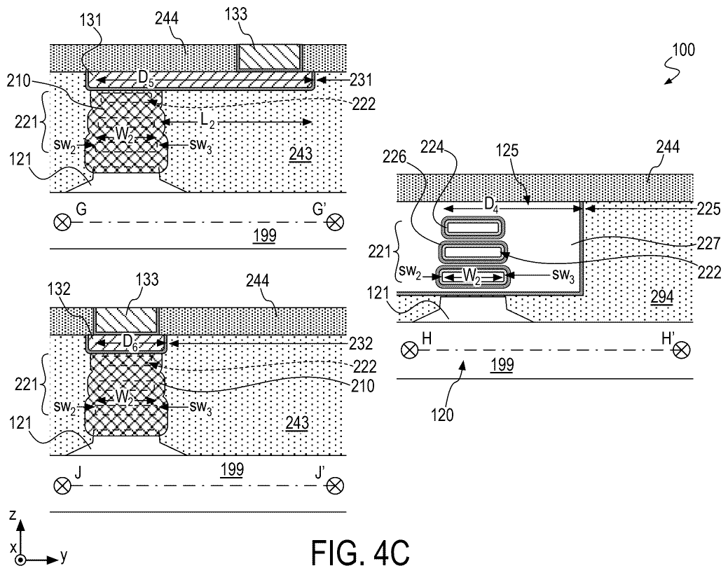

FIGS. 4A, 4B, and 4C illustrate plan and cross-sectional profile views of an IC device 100 having unaligned endcaps of electrodes 125 and contacts 131, 132, including a narrow portion of semiconductor region 121A in transistor structure 101C, in accordance with some embodiments. FIGS. 4A-4C show additional detail of transistor structure 101C (e.g., as described at FIG. 1), including various embodiments of semiconductor region 121A. FIG. 4A illustrates a plan view of semiconductor region 121A in device 100, including a magnified view of transistor structure 101C having the portion of semiconductor region 121A with narrow width W₂. The plan view of FIG. 4A shows the orientation of the cross-sectional views G-G′, H-H′, and J-J′ of FIGS. 4B and 4C. FIG. 4A also illustrates structures 141, 142 to either side of channel region 120 and contacts 131, 132 in structure 101C, including structure 142 over a transition portion of semiconductor region 121A between widths W₁, W₂.

Semiconductor region 121A and channel region 120 have width W₂ between sidewalls sw₂, sw₃ in transistor structure 101C. Width W₂ of region 121A in transistor structure 101C is less than widths W₃, W₁ of region 121A in transistor structures 101A, 101B. Channel region 120 (of both transistor structure 101C and semiconductor region 121A) extends in the x-direction between source and drain bodies 210 under contacts 131, 132. Gate electrode 125 is between the source and drain bodies 210 of transistor structure 101C and on and over channel region 120. Gate electrode 125 extends over channel region 120 in the y-direction. Electrode 125 extends beyond a sidewall sw₃ of channel region 120 to distance D₄ from sidewall sw₂. Contacts 131, 132 extend in the y-direction beyond sidewall sw₃ to distances D₅, D₆, respectively, from sidewall sw₂. Distance D₅ from sidewall sw₂ in transistor structure 101C is equal to each of distances D₂ from sidewall sw₂ in transistor structures 101A, 101B. Notably, distance D₅ is greater than distance D₄, and distance D₄ is greater than distance D₆.

FIG. 4B shows cross-sectional profile views of transistor structure 101C, including gate electrode 125 on channel region 120 and contacts 131, 132 on source and drain bodies 210. View G-G′ illustrates source contact 131 on source body 210. View H-H′ shows gate electrode 125 on channel region 120. View J-J′ illustrates drain contact 132 on drain body 210. In the embodiments of FIG. 4B, transistor structure 101C, channel region 120, and semiconductor region 121A include a single semiconductor fin 220 in width W₂.

Sidewalls sw₂, sw₃ of regions 120, 121A in transistor structure 101C are sidewalls sw₂, sw₃ of semiconductor fin 220. Width W₂ of region 121A in transistor structure 101C is less than width W₁ of region 121A in transistor structure 101B (e.g., because width W₁ of regions 120, 121A in structure 101B includes two semiconductor fins 220, and width W₂ of regions 120, 121A in structure 101C includes a single semiconductor fin 220).

View G-G′ of FIG. 4B shows source contact 131 on source body 210. In the example of transistor structure 101C and FIGS. 4A-4C, contact 131 extends in the y-direction to sidewall 231 beyond sidewall sw₃ to distance D₅ from sidewall sw₂ greater than both distance D₄ to sidewall 225 of electrode 125 and distance D₆ to sidewall 232 of contact 132.

Contact 131 of transistor structure 101C extends to the same distance D₅ (or distance D₂; between sidewalls sw₂, 231) as contact 131 of transistor structures 101A, 101B, but with narrower width W₂ (relative to widths W₃, W₁ of structures 101A, 101B) and longer length L₂ (beyond sidewall sw₃), contact 131 provides an additional contact area on body 210 (relative to structure 101A) below an upper surface of body 210, around to a side of body 210.

View H-H′ of FIG. 4B illustrates gate electrode 125 on channel region 120, over fins 220 and in and over isolation material 294 over substrate 199. Gate electrode 125 extends in the y-direction to sidewall 225 (of electrode 125) beyond sidewall sw₃ (of region 120) to distance D₄ (greater than width W₂) from sidewall sw₂.

The reduced distance D₄ (e.g., relative to distance D₅ of contact 131 in transistor structure 101C and/or to distances D₂, D₁ of electrode 125 in transistor structures 101A, 101B) may improve the device performance of transistor structure 101C by reducing the parasitic capacitances between transistor structure 101C terminals. The reduced distance D₄ (e.g., relative to distances D₂, D₁ of electrode 125 in transistor structures 101A, 101B) may affect the performance of transistor structure 101C by shifting threshold voltage V_{T} of structure 101C due to DIBL and/or the different volume and distribution of metals 226, 227 in electrodes 125.

View J-J′ of FIG. 4B shows drain contact 132 on drain body 210. In the example of transistor structure 101C and FIGS. 4A-4C, contact 132 extends in the y-direction to sidewall 232 beyond sidewall sw₃ to distance De from sidewall sw₂ less than distance D₄ to sidewall 225 of electrode 125 and less than distance D₅ to sidewall 231 of contact 131.

The reduced distance D₆ (e.g., relative to distance D₅ of contact 131 and distance D₄ of electrode 125 in transistor structure 101C) may improve the device performance of transistor structure 101C by reducing the parasitic capacitances between transistor structure 101C terminals. Contact 132 of transistor structure 101C extends to sufficient distance D₆ (e.g., beyond sidewall sw₃ and greater than width W₂) to provide contact area on body 210, although the reduced contact area (e.g., relative to transistor structures 101A, 101B) may result in elevated contact resistance, which may be utilized in applications of structure 101C in device 100 where low current (e.g., low leakage current) is desired.

FIG. 4C shows cross-sectional profile views of transistor structure 101C, including gate electrode 125 on channel region 120 and contacts 131, 132 on source and drain bodies 210. View G-G′ shows source contact 131 on source body 210. View H-H′ shows gate electrode 125 on channel region 120. View J-J′ shows drain contact 132 on drain body 210. In the embodiments of FIG. 4C, transistor structure 101C, channel region 120, and semiconductor region 121A include a group (e.g., stack 221) of multiple semiconductor nanoribbons 222 in width W₂.

Sidewalls sw₂, sw₃ of regions 120, 121A in transistor structure 101C are sidewalls sw₂, sw₃ of nanoribbons 222. Width W₂ of region 121A in transistor structure 101C is less than widths W₃, W₁ of region 121A in transistor structures 101A, 101B (e.g., because regions 120, 121A in structure 101C have narrower width W₂ of semiconductor nanoribbons 222 than the wider widths W₃, W₁ of nanoribbons 222 of regions 120, 121A in structures 101A, 101B).

View G-G′ of FIG. 4C shows source contact 131 on source body 210. In the example of transistor structure 101C and FIGS. 4A-4C, contact 131 extends in the y-direction to sidewall 231 beyond sidewall sw₃ to distance D₅ from sidewall sw₂ greater than both distance D₄ to sidewall 225 of electrode 125 and distance D₆ to sidewall 232 of contact 132.

Contact 131 of transistor structure 101C extends to the same distance D₅ (or distance D₂; between sidewalls sw₂, 231) as contact 131 of transistor structures 101A, 101B, but with narrower width W₂ (relative to widths W₃, W₁ of structures 101A, 101B) and longer length L₂ (beyond sidewall sw₃).

View H-H′ of FIG. 4C illustrates gate electrode 125 on channel region 120, over and around nanoribbons 222 and in and over isolation material 294 over substrate 199. Gate electrode 125 extends in the y-direction to sidewall 225 (of electrode 125) beyond sidewall sw₃ (of region 120) to distance D₄ (greater than width W₂) from sidewall sw₂.

The reduced distance D₄ (e.g., relative to distance D₅ of contact 131 in transistor structure 101C and/or to distances D₂, D₁ of electrode 125 in transistor structures 101A, 101B) may improve the device performance of transistor structure 101C by reducing the parasitic capacitances between transistor structure 101C terminals. The reduced distance D₄ (e.g., relative to distances D₂, D₁ of electrode 125 in transistor structures 101A, 101B) may affect the performance of transistor structure 101C by shifting threshold voltage V_{T} of structure 101C due to DIBL and/or the different volume and distribution of metals 226, 227 in electrodes 125.

View J-J′ of FIG. 4C shows drain contact 132 on drain body 210. In the example of transistor structure 101C and FIGS. 4A-4C, contact 132 extends in the y-direction to sidewall 232 beyond sidewall sw₃ to distance D₆ from sidewall sw₂ less than distance D₄ to sidewall 225 of electrode 125 and less than distance D₅ to sidewall 231 of contact 131.

The reduced distance D₆ (e.g., relative to distance D₅ of contact 131 and distance D₄ of electrode 125 in transistor structure 101C) may improve the device performance of transistor structure 101C by reducing the parasitic capacitances between transistor structure 101C terminals. Contact 132 of transistor structure 101C extends to sufficient distance D₆ (e.g., beyond sidewall sw₃ and greater than width W₂) to provide contact area on body 210, although the reduced contact area (e.g., relative to transistor structures 101A, 101B) may result in elevated contact resistance, which may be utilized in applications of structure 101C in device 100 where low current (e.g., low leakage current) is desired.

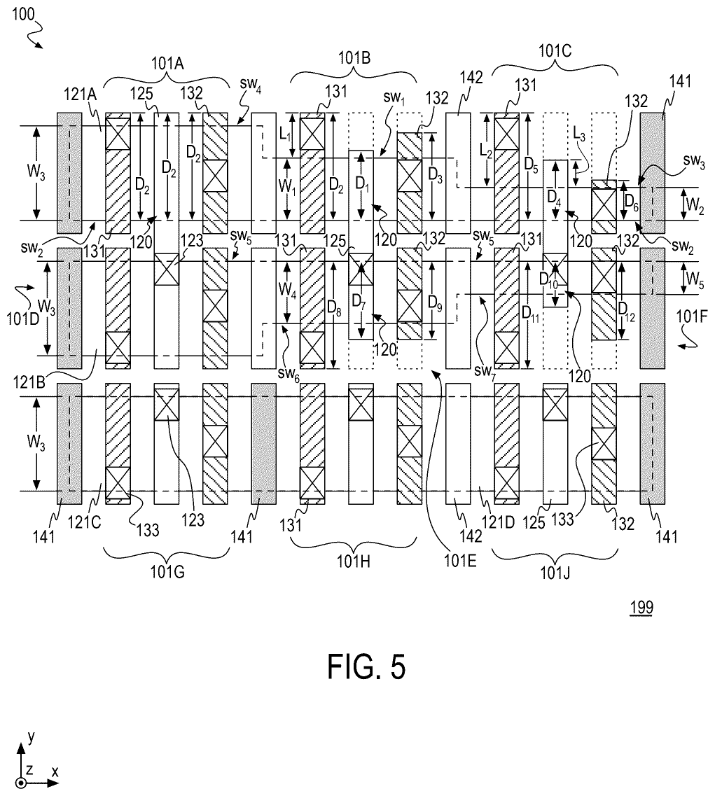

FIG. 5 illustrates a plan view of an IC device 100 having unaligned endcaps of gate electrodes 125 and source and drain contacts 131, 132 in adjacent transistor structures 101, in accordance with some embodiments. FIG. 5 shows embodiments similar to those described at FIG. 1. Notably, some electrodes 125 and drain contacts 132 have different dimensions (e.g., distances D₇, D₉, D₁₀, D₁₂).

In some embodiments, as in the example of FIG. 1, pairs of transistor structures 101 with shared gate electrodes 125 (such as structures 101B, 101E and structures 101C, 101F) are tuned together (e.g., fabricated to have similar or the same dimensions for corresponding electrodes 125 and contacts 131, 132). For example, structures 101B, 101E may be a pair (e.g., a complementary pair) with widths W₁, W₄ approximately equal, distances D₁, D₇ approximately equal, distances D₂, D₈ approximately equal, and distances D₃, D₉ approximately equal. Structures 101C, 101F may be a pair (e.g., a complementary pair) with widths W₂, W₅ approximately equal, distances D₄, D₁₀ approximately equal, distances D₅, D₁₁ approximately equal, and distances D₆, D₁₂ approximately equal. In some embodiments, as in the example of FIG. 1, transistor structures 101 using complementary pairs of adjacent semiconductor regions 121 (e.g., regions 121A, 121B) are symmetrical about a line of reflection between the regions 121.

In other embodiments, as in the example of FIG. 5, pairs of transistor structures 101 with shared gate electrodes 125 (such as structures 101B, 101E and structures 101C, 101F) do not have mirror symmetry. For example, structures 101B, 101E in FIG. 5 have same widths W₁, W₄, but different distances D₁, D₇ for electrodes 125 and different distances D₃, D₉ for contacts 132. As another example, structures 101C, 101F in FIG. 5 have same widths W₂, W₅, but different distances D₄, D₁₀ for electrodes 125 and different distances D₆, D₁₂ for contacts 132. Dimensions of gate electrodes 125 and source and drain contacts 131, 132 can be designed and set using any suitable means. In some embodiments, dimensions of gate electrodes 125 and source and drain contacts 131, 132 are designed and set based on simulation data. In some embodiments, dimensions of gate electrodes 125 and source and drain contacts 131, 132 are designed and set iteratively, e.g., based on test data.

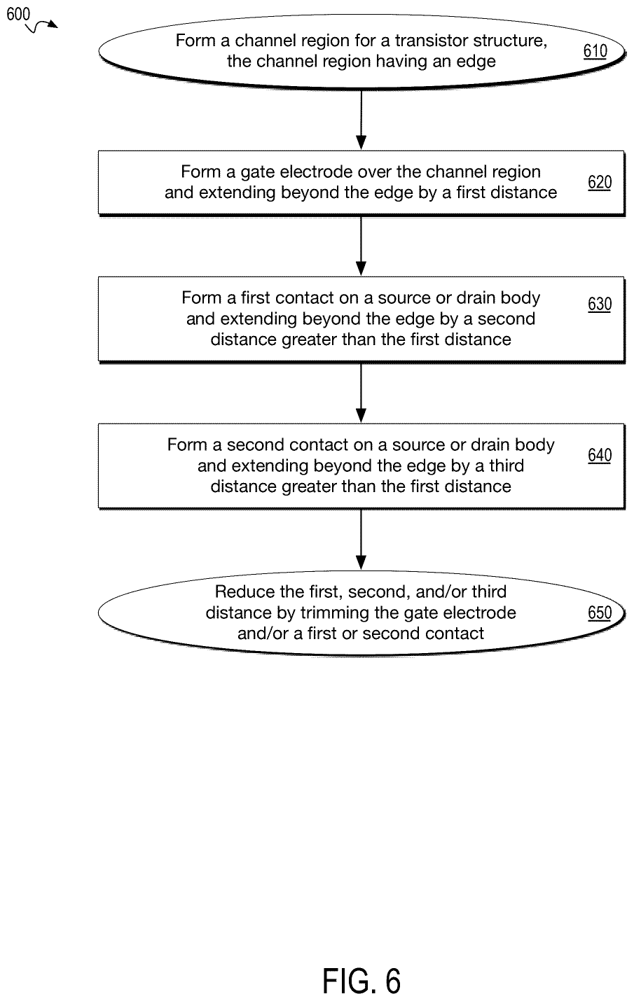

FIG. 6 is a flow chart of methods 600 for forming a transistor structure with unaligned endcaps of gate electrodes and source and drain contacts, in accordance with some embodiments. Methods 600 include operations 610-650. Some operations shown in FIG. 6 are optional. Additional operations may be included. FIG. 6 shows an example sequence, but the operations can be done in other orders as well, and some operations may be omitted. Some operations can also be performed multiple times before other operations are performed. For example, multiple channel regions may be formed before electrodes or contacts are formed. Some operations may be included within other operations so that the number of operations illustrated FIG. 6 is not a limitation of the methods 600.

Methods 600 begin at operation 610 with receiving or forming a channel region. The channel region may have first and second edges or sidewalls with a width between the first and second edges. The channel region may be any suitable structure or material(s) (such as described of channel regions 120 at least at FIGS. 1-2C) and may be formed by any suitable means. In many embodiments, the channel region is formed from a substrate (for example, a wafer or die as described of substrate 199 at FIG. 1). The substrate may be of a semiconductor material or a crystalline material capable of serving as a growth template for growth of a semiconductor material. In some embodiments, the channel region is formed by growing semiconductor material over the substrate, e.g., in a stack of layers. In some embodiments, the channel region is formed by etching the channel region from the substrate. For example, a fin of semiconductor material may be etched in or from the substrate. In some embodiments, the fin of semiconductor material is a semiconductor region that is further cut (e.g., etched) into segments that may each serve as a channel region. In some such embodiments, the fin of semiconductor material is a stack of material layers that may be further processed into nanoribbons (e.g., nanowires or nanosheets).

The channel region may couple a pair of source and drain bodies. In many embodiments, the source and drain bodies are formed from the channel region, e.g., one body from each end of a fin or nanoribbon channel region. The source and drain bodies may be formed by any suitable means, for example, epitaxially from the channel region as a growth template.

Methods 600 continue with forming a gate electrode over the channel region at operation 620. The gate electrode may be any suitable structure or material(s) (such as described of gate electrode 125 at least at FIGS. 1-2C) and may be formed by any suitable means. In many embodiments, the gate electrode includes one or more dielectric (or other insulator) layers, which may be deposited (e.g., conformally) over the channel region. The gate insulator may include one or more of low-K and high-K layers. One or more metals may be deposited over the gate insulator, for example, a conformally deposited liner layer and a fill metal on, over, and within the liner layer. One or more gate metals may be workfunction metals.

The gate electrode may be formed by depositing gate electrode materials to the desired dimensions, e.g., using a lithographic patterning process. For example, a cavity may be formed by removing (e.g., etching out) dielectric material from an unmasked portion of the substrate around the channel region, and gate dielectrics and metals may be deposited in the patterned cavity. The gate electrode (e.g., including gate dielectrics and metals) may be deposited on and over (and, in some embodiments, around) the channel region (e.g., one or more fins or nanoribbons) so that the gate electrode extends beyond the first and second edges or sidewalls of the channel region. The gate electrode may be fabricated with dimensions to set device characteristics (such as parasitic capacitances and threshold voltage V_{T}), for example, as described elsewhere herein. The gate electrode may be fabricated to extend beyond a first edge of the channel region by a first distance.

Methods 600 continue at operation 630 with forming a contact on one of a source or drain coupled with the channel region. The source or drain contact may be any suitable structure or material(s) (such as described of contacts 131, 132 at least at FIGS. 1-2C) and may be formed by any suitable means. The source or drain contact may be formed by depositing one or more metals over an exposed portion of a source or drain body, for example, by conformally depositing a liner layer on the source or drain body and then a fill metal on, over, and within the liner layer. The exposed portion of the source or drain body may be exposed by removing (e.g., etching out) a portion of a dielectric material over the source or drain body, and the retained dielectric material may serve as a template for contact deposition. For example, the contact metal(s) may be deposited in a void or cavity in the dielectric material and over the source or drain body (e.g., with the dimensions of the contact set by the patterning of the dielectric material). The source or drain contact may be fabricated with dimensions to set device characteristics (such as parasitic capacitances), for example, in coordination the formation of the gate electrode, as described elsewhere herein. The source or drain contact may be fabricated to extend beyond the first edge of the channel region by a second distance. The second distance may be greater than, less than, or equal to the first distance.

Methods 600 continue with forming a second contact on the other of the source or drain coupled with the channel region at operation 640. The second source or drain contact may be formed much as described at operation 630 (e.g., and of contacts 131, 132 at least at FIGS. 1-2C). The second source or drain contact may be fabricated with dimensions to set device characteristics (such as parasitic capacitances), for example, in coordination the formation of the gate electrode and the first source or drain contact, as described elsewhere herein. The second source or drain contact may be fabricated to extend beyond the first edge of the channel region by a third distance. The third distance may be greater than, less than, or equal to either and/or both of the first and second distances.

Methods 600 continue at operation 650 with optionally reducing a dimension of a transistor structure. For example, any of the first, second, or third distances may be reduced by reducing a length of the first or second source or drain contact or of the gate electrode. These structure dimensions may be reduced by trimming the first or second source or drain contact or of the gate electrode, e.g., by a metal etch (such as a metal gate cut or similar operation). In some embodiments, the etch cuts off an end portion of the first or second source or drain contact or of the gate electrode. In some embodiments, the etch cuts through at least one of the first or second source or drain contacts or the gate electrode, for example, separating the first or second contacts or the gate electrode into multiple contacts or electrodes.

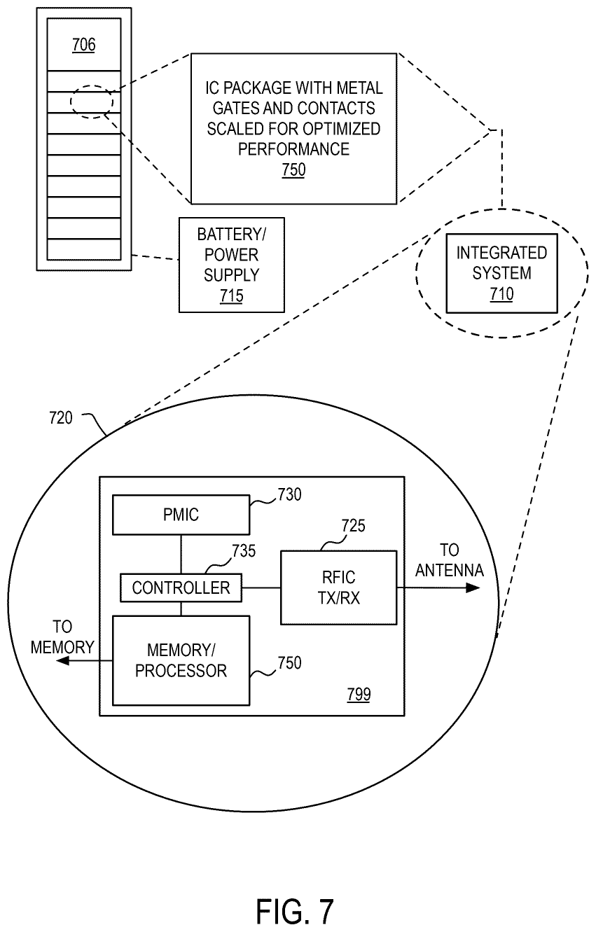

FIG. 7 illustrates a diagram of an example data server machine 706 employing an IC device having a transistor with an unaligned source or drain contact or gate electrode, in accordance with some embodiments. Server machine 706 may be any commercial server, for example, including any number of high-performance computing platforms disposed within a rack and networked together for electronic data processing, which in the exemplary embodiment includes one or more devices 750 having a transistor with an unaligned source or drain contact or gate electrode.

Also as shown, server machine 706 includes a battery and/or power supply 715 to provide power to devices 750, and to provide, in some embodiments, power delivery functions such as power regulation. Devices 750 may be deployed as part of a package-level integrated system 710. Integrated system 710 is further illustrated in the expanded view 720. In the exemplary embodiment, devices 750 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 750 is a microprocessor including a static RAM (SRAM) cache memory. As shown, device 750 may be an IC device having a transistor with an unaligned source or drain contact or gate electrode, as discussed herein. Device 750 may be further coupled to (e.g., communicatively coupled to) a board, an interposer, or a substrate 799 along with, one or more of a power management IC (PMIC) 730, RF (wireless) IC (RFIC) 725 including a wideband RF (wireless) transmitter and/or receiver (TX/RX) (e.g., including a digital baseband and an analog front end module further includes a power amplifier on a transmit path and a low noise amplifier on a receive path), and a controller 735 thereof. In some embodiments, RFIC 725, PMIC 730, controller 735, and device 750 include having a transistor with an unaligned source or drain contact or gate electrode.

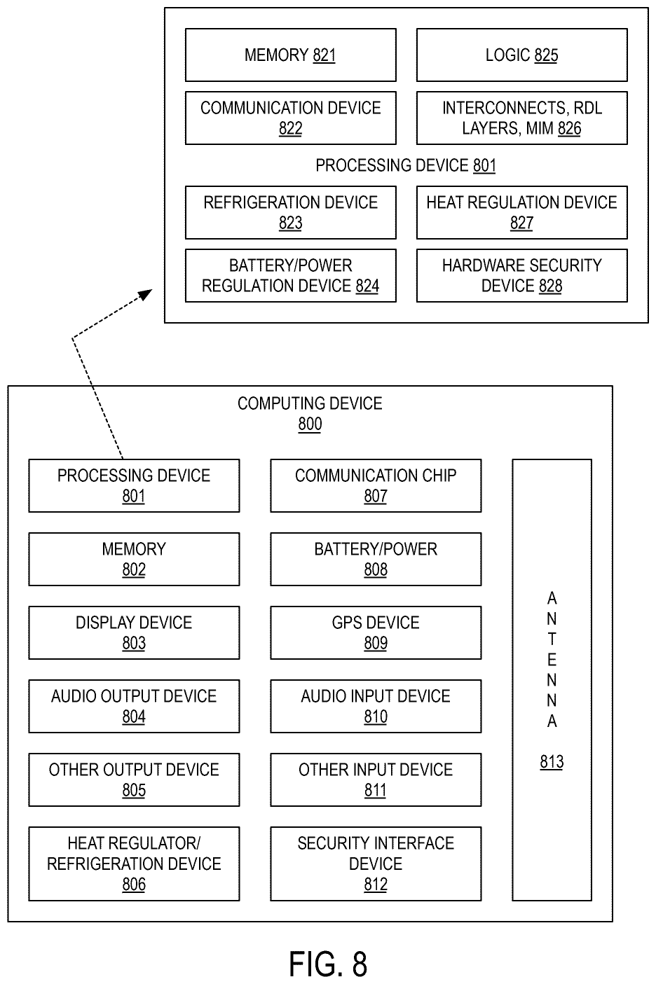

FIG. 8 is a block diagram of an example computing device 800, in accordance with some embodiments. For example, one or more components of computing device 800 may include any of the devices or structures discussed herein. A number of components are illustrated in FIG. 8 as being included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled. In another set of examples, computing device 800 may not include an audio output device 804, other output device 805, global positioning system (GPS) device 809, audio input device 810, or other input device 811, but may include audio output device interface circuitry, other output device interface circuitry, GPS device interface circuitry, audio input device interface circuitry, audio input device interface circuitry, to which audio output device 804, other output device 805, GPS device 809, audio input device 810, or other input device 811 may be coupled.

Computing device 800 may include a processing device 801 (e.g., one or more processing devices). As used herein, the term “processing device” or “processor” indicates a device that processes electronic data from registers and/or memory to transform that electronic data into other electronic data that may be stored in registers and/or memory. Processing device 801 may include a memory 821, a communication device 822, a refrigeration device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 800 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 802 includes memory that shares a die with processing device 801. This memory may be used as cache memory and may include embedded dynamic random-access memory (eDRAM) or spin transfer torque magnetic random-access memory (STT-MRAM).

Computing device 800 may include a heat regulation/refrigeration device 806. Heat regulation/refrigeration device 806 may maintain processing device 801 (and/or other components of computing device 800) at a predetermined low temperature during operation.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a GPS device 809 (or corresponding interface circuitry, as discussed above). GPS device 809 may be in communication with a satellite-based system and may receive a location of computing device 800, as known in the art.

Computing device 800 may include other output device 805 (or corresponding interface circuitry, as discussed above). Examples of the other output device 805 may include an audio codec, a video codec, a printer, a wired or wireless transmitter for providing information to other devices, or an additional storage device.

Computing device 800 may include other input device 811 (or corresponding interface circuitry, as discussed above). Examples of the other input device 811 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, access list management, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-8. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a channel region extending in a first direction between source and drain bodies in a transistor structure, wherein the source and drain bodies include an impurity-doped semiconductor material, a gate electrode between the source and drain bodies and over the channel region, wherein the gate electrode extends in a second direction, orthogonal to the first direction, beyond a first edge of the channel region to a first distance from a second edge, opposite the first edge, and first and second metallization structures extending in the second direction, wherein the first metallization structure is over and in contact with a first of the source and drain bodies and extends beyond the first edge to a second distance from the second edge of the channel region, the second metallization structure is over and in contact with a second of the source and drain bodies and extends beyond the first edge to a third distance from the second edge of the channel region, the second distance is greater than the third distance, and the third distance is greater than the first distance.

In one or more second embodiments, further to the first embodiments, the transistor structure is a first transistor structure, the source and drain bodies are first source and drain bodies, the gate electrode is a first gate electrode, the channel region is a first channel region, a semiconductor region includes the first channel region and the first and second edges, the semiconductor region extends beyond the first transistor structure and includes a second channel region between second source and drain bodies in a second transistor structure, a second gate electrode is between the second source and drain bodies and over the second channel region, the second gate electrode extending in the second direction to a fourth distance from the second edge of the second channel region, and third and fourth metallization structures extending in the second direction, wherein the third metallization structure is over and in contact with a first of the second source and drain bodies and extends to a fifth distance from the second edge of the second channel region, the fourth metallization structure is over and in contact with a second of the second source and drain bodies and extends to a sixth distance from the second edge of the second channel region, the fifth distance is greater than the fourth distance, and the fourth distance is greater than the sixth distance.

In one or more third embodiments, further to the first or second embodiments, the first channel region includes a first width between the first and second edges in the first transistor structure, the second channel region includes a second width between the second edge and a third edge in the second transistor structure, the third edge opposite the second edge, and the first width is greater than the second width.

In one or more fourth embodiments, further to the first through third embodiments, the first metallization structure extends a first length beyond the first edge of the semiconductor region, the third metallization structure extends a second length beyond the third edge of the semiconductor region, the second length is greater than the first length, and the second and fifth distances are approximately equal.

In one or more fifth embodiments, further to the first through fourth embodiments, the semiconductor region includes a plurality of semiconductor fins, the semiconductor region includes a first quantity of the semiconductor fins in the first channel region, and the semiconductor region includes a second quantity of the semiconductor fins in the second channel region, the first quantity greater than the second quantity.

In one or more sixth embodiments, further to the first through fifth embodiments, the transistor structure is a first transistor structure, the source and drain bodies are first source and drain bodies, the gate electrode is a first gate electrode, the channel region is a first channel region, including a first width between the first and second edges in the first transistor structure, a semiconductor region includes the first channel region and the first and second edges, the semiconductor region extends beyond the first transistor structure and includes a third channel region between third source and drain bodies in a third transistor structure, the third channel region including a third width between the second edge and an opposing fourth edge, the third width is greater than the first width, a third gate electrode is between the third source and drain bodies and over the third channel region, a fifth metallization structure is over and in contact with a first of the third source and drain bodies, a sixth metallization structure is over and in contact with a second of the third source and drain bodies, and the third gate electrode and the fifth and sixth metallization structures extend in the second direction beyond the fourth edge to at least the second distance from the second edge of the semiconductor region.

In one or more seventh embodiments, further to the first through sixth embodiments, the transistor structure is a first transistor structure of a first conductivity type, the source and drain bodies are first source and drain bodies, the channel region is a first channel region, a first semiconductor region includes the first channel region and the first and second edges, a second semiconductor region includes a fourth channel region and fifth and sixth edges, the fourth channel region between fourth source and drain bodies in a fourth transistor structure of a second conductivity type, the second conductivity type complementary to the first conductivity type, the gate electrode extends between the fourth source and drain bodies and over the fourth channel region to beyond the sixth edge of the fourth channel region to a seventh distance from the fifth edge, the fifth edge adjacent the second edge and opposite the sixth edge, seventh and eighth metallization structures extend in the second direction, the seventh metallization structure over and in contact with a first of the fourth source and drain bodies and extending to an eighth distance from the fifth edge of the fourth channel region, the eighth metallization structure over and in contact with a second of the fourth source and drain bodies and extending to a ninth distance from the fifth edge of the fourth channel region, the eighth distance is greater than the ninth distance, and the ninth distance is greater than the seventh distance.

In one or more eighth embodiments, further to the first through seventh embodiments, the first semiconductor region extends beyond the first transistor structure and includes a second channel region between second source and drain bodies in a second transistor structure of the first conductivity type, the first channel region includes a first width greater than a second width of the second channel region, the second semiconductor region extends beyond the fourth transistor structure and includes a fifth channel region between fifth source and drain bodies in a fifth transistor structure of the second conductivity type, the fourth channel region includes a fourth width greater than a fifth width of the fifth channel region, a second gate electrode is over the second and fifth channel regions, between the second source and drain bodies and between the fifth source and drain bodies, the second gate electrode extending in the second direction to a fourth distance from the second edge of the second channel region and to a tenth distance from the fifth edge of the fifth channel region, third and fourth metallization structures extend in the second direction, the third metallization structure over and in contact with a first of the second source and drain bodies, the fourth metallization structure over and in contact with a second of the second source and drain bodies and extending to a sixth distance from the second edge of the second channel region, the fourth distance is greater than the sixth distance, ninth and tenth metallization structures extend in the second direction, the ninth metallization structure over and in contact with a first of the fifth source and drain bodies, the tenth metallization structure over and in contact with a second of the fifth source and drain bodies and extending to an eleventh distance from the fifth edge of the fifth channel region, and the tenth distance is greater than the eleventh distance.

In one or more ninth embodiments, an apparatus includes a channel region extending in a first direction between source and drain bodies in a transistor structure, wherein the source and drain bodies include an impurity-doped semiconductor material, a gate electrode between the source and drain bodies and over the channel region, wherein the gate electrode extends in a second direction, orthogonal to the first direction, beyond a first edge of the channel region to a first distance from a second edge, opposite the first edge, and first and second metallization structures extending in the second direction, wherein the first metallization structure is over and in contact with a first of the source and drain bodies and extends beyond the first edge to a second distance from the second edge of the channel region, the second metallization structure is over and in contact with a second of the source and drain bodies and extends beyond the first edge to a third distance from the second edge of the channel region, the second distance is greater than the first distance, and the first distance is greater than the third distance.

In one or more tenth embodiments, further to the ninth embodiments, the transistor structure is a first transistor structure, the source and drain bodies are first source and drain bodies, the gate electrode is a first gate electrode, the channel region is a first channel region, a semiconductor region includes the first channel region and the first and second edges, the semiconductor region extends beyond the first transistor structure and includes a second channel region between second source and drain bodies in a second transistor structure, a second gate electrode is between the second source and drain bodies and over the second channel region, the second gate electrode extending in the second direction to a fourth distance from the second edge of the second channel region, and third and fourth metallization structures extending in the second direction, wherein the third metallization structure is over and in contact with a first of the second source and drain bodies and extends to a fifth distance from the second edge of the channel region, the fourth metallization structure is over and in contact with a second of the second source and drain bodies and extends to a sixth distance from the second edge of the channel region, the fifth distance is greater than the fourth distance, and the sixth distance is greater than the fourth distance.

In one or more eleventh embodiments, further to the ninth or tenth embodiments, the first channel region includes a first width between the first and second edges in the first transistor structure, the second channel region includes a second width between the second edge and a third edge in the second transistor structure, the third edge opposite the second edge, and the second width is greater than the first width.

In one or more twelfth embodiments, further to the ninth through eleventh embodiments, the second and fifth distances are approximately equal.

In one or more thirteenth embodiments, further to the ninth through twelfth embodiments, the semiconductor region includes a plurality of nanoribbons.

In one or more fourteenth embodiments, further to the ninth through thirteenth embodiments, the transistor structure is a first transistor structure of a first conductivity type, the source and drain bodies are first source and drain bodies, the channel region is a first channel region, a first semiconductor region includes the first channel region and the first and second edges, a second semiconductor region includes a second channel region and third and fourth edges, the second channel region between second source and drain bodies in a second transistor structure of a second conductivity type, the second conductivity type complementary to the first conductivity type, the gate electrode extends between the second source and drain bodies and over the second channel region to beyond the fourth edge of the second channel region to a fourth distance from the third edge, the third edge adjacent the second edge and opposite the fourth edge, third and fourth metallization structures extend in the second direction, the third metallization structure over and in contact with a first of the second source and drain bodies and extending to a fifth distance from the third edge of the second channel region, the fourth metallization structure over and in contact with a second of the second source and drain bodies and extending to a sixth distance from the third edge of the second channel region, the fifth distance is greater than the fourth distance, and the fourth distance is greater than the sixth distance.

In one or more fifteenth embodiments, further to the ninth through fourteenth embodiments, the first semiconductor region extends beyond the first transistor structure and includes a third channel region between third source and drain bodies in a third transistor structure of the first conductivity type, the second semiconductor region extends beyond the second transistor structure and includes a fourth channel region between fourth source and drain bodies in a fourth transistor structure of the second conductivity type, the third and fourth channel regions include a first width greater than a second width of the first and second channel regions, a second gate electrode is over the third and fourth channel regions, between the third source and drain bodies and between the fourth source and drain bodies, the second gate electrode extending in the second direction to a seventh distance from the second edge of the third channel region and to an eighth distance from the third edge of the fourth channel region, fifth and sixth metallization structures extend in the second direction, the fifth metallization structure over and in contact with a first of the third source and drain bodies, the sixth metallization structure over and in contact with a second of the third source and drain bodies and extending to a ninth distance from the second edge of the third channel region, the ninth distance is greater than the seventh distance, seventh and eighth metallization structures extend in the second direction, the seventh metallization structure over and in contact with a first of the fourth source and drain bodies, the eighth metallization structure over and in contact with a second of the fourth source and drain bodies and extending to a tenth distance from the third edge of the fourth channel region, and the tenth distance is greater than the eighth distance.

In one or more sixteenth embodiments, an apparatus includes a semiconductor region extending in a first direction and including first and second widths, the first width in a channel region between source and drain bodies in a transistor structure, one of the source and drain bodies between the first and second widths, a gate electrode between the source and drain bodies and over the channel region, wherein the gate electrode extends in a second direction, orthogonal to the first direction, beyond an edge of the channel region to a first distance from the edge of the channel region, a first metallization structure over and in contact with a first of the source and drain bodies and extending in the second direction to a second distance from the edge of the channel region greater than the first distance, and a second metallization structure over and in contact with a second of the source and drain bodies and extending in the second direction to a third distance from the edge of the channel region, wherein the second distance is greater than the third distance.

In one or more seventeenth embodiments, further to the sixteenth embodiments, the transistor structure is a first transistor structure, the source and drain bodies are first source and drain bodies, the gate electrode is a first gate electrode, the channel region is a first channel region, the semiconductor region includes the edge and a second channel region with the second width between second source and drain bodies in a second transistor structure, the second width is greater than the first width, a second gate electrode is between the second source and drain bodies and over the second channel region, and third and fourth metallization structures, wherein the third metallization structure is over and in contact with a first of the second source and drain bodies, the fourth metallization structure is over and in contact with a second of the second source and drain bodies, and the second gate electrode and the third and fourth metallization structures extend in the second direction to at least the second distance from the edge of the second channel region.

In one or more eighteenth embodiments, further to the sixteenth or seventeenth embodiments, the semiconductor region includes a third channel region with a third width between third source and drain bodies in a third transistor structure, the first width is greater than the third width, a third gate electrode is between the third source and drain bodies and over the third channel region, the third gate electrode extending in the second direction to a fourth distance from the edge of the second channel region, fifth and sixth metallization structures extend in the second direction, the fifth metallization structure over and in contact with a first of the third source and drain bodies and extending to a fifth distance from the edge of the second channel region, the sixth metallization structure over and in contact with a second of the third source and drain bodies and extending to a sixth distance from the edge of the second channel region, the third distance is greater than the first distance, the second distance is greater than or equal to the fifth distance, and the fourth distance is greater than the sixth distance.

In one or more nineteenth embodiments, further to the sixteenth through eighteenth embodiments, the transistor structure is a first transistor structure, the source and drain bodies are first source and drain bodies, the gate electrode is a first gate electrode, the channel region is a first channel region, the semiconductor region includes the edge and a second channel region with the second width between second source and drain bodies in a second transistor structure, the first width is greater than the second width, the third distance is greater than the first distance, a second gate electrode is between the second source and drain bodies and over the second channel region, the second gate electrode extending in the second direction to a fourth distance from the edge of the second channel region, and third and fourth metallization structures extend in the second direction, the third metallization structure over and in contact with a first of the second source and drain bodies and extending to a fifth distance from the edge of the second channel region, the fourth metallization structure over and in contact with a second of the second source and drain bodies and extending to a sixth distance from the edge of the second channel region, the fifth distance is greater than the fourth distance, and the fourth distance is greater than the sixth distance.

In one or more twentieth embodiments, further to the sixteenth through nineteenth embodiments, the semiconductor region is a first semiconductor structure, the first and second transistor structures are of a first conductivity type, a second semiconductor region includes a second edge and third and fourth channel regions in third and fourth transistor structures of a second conductivity type, the second conductivity type complementary to the first conductivity type, the third channel region including the first width between third source and drain bodies, the fourth channel region including the second width between fourth source and drain bodies, the first gate electrode extends between the third source and drain bodies and over the third channel region to less than the second distance from the second edge, and the second gate electrode extends between the fourth source and drain bodies and over the fourth channel region to less than the second distance from the second edge.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a channel region extending in a first direction between source and drain bodies in a transistor structure, wherein the source and drain bodies comprise an impurity-doped semiconductor material;
a gate electrode between the source and drain bodies and over the channel region, wherein the gate electrode extends in a second direction, orthogonal to the first direction, beyond a first edge of the channel region to a first distance from a second edge, opposite the first edge; and
first and second metallization structures extending in the second direction, wherein the first metallization structure is over and in contact with a first of the source and drain bodies and extends beyond the first edge to a second distance from the second edge of the channel region, the second metallization structure is over and in contact with a second of the source and drain bodies and extends beyond the first edge to a third distance from the second edge of the channel region, the second distance is greater than the third distance, and the third distance is greater than the first distance.

2. The apparatus of claim 1, wherein:
the transistor structure is a first transistor structure;
the source and drain bodies are first source and drain bodies;
the gate electrode is a first gate electrode;
the channel region is a first channel region;
a semiconductor region comprises the first channel region and the first and second edges;
the semiconductor region extends beyond the first transistor structure and comprises a second channel region between second source and drain bodies in a second transistor structure;
a second gate electrode is between the second source and drain bodies and over the second channel region, the second gate electrode extending in the second direction to a fourth distance from the second edge of the second channel region; and
third and fourth metallization structures extending in the second direction, wherein the third metallization structure is over and in contact with a first of the second source and drain bodies and extends to a fifth distance from the second edge of the second channel region, the fourth metallization structure is over and in contact with a second of the second source and drain bodies and extends to a sixth distance from the second edge of the second channel region, the fifth distance is greater than the fourth distance, and the fourth distance is greater than the sixth distance.

3. The apparatus of claim 2, wherein:
the first channel region comprises a first width between the first and second edges in the first transistor structure;
the second channel region comprises a second width between the second edge and a third edge in the second transistor structure, the third edge opposite the second edge; and
the first width is greater than the second width.

4. The apparatus of claim 3, wherein:
the first metallization structure extends a first length beyond the first edge of the semiconductor region;
the third metallization structure extends a second length beyond the third edge of the semiconductor region;
the second length is greater than the first length; and
the second and fifth distances are approximately equal.

5. The apparatus of claim 3, wherein:
the semiconductor region comprises a plurality of semiconductor fins;
the semiconductor region comprises a first quantity of the semiconductor fins in the first channel region; and
the semiconductor region comprises a second quantity of the semiconductor fins in the second channel region, the first quantity greater than the second quantity.

6. The apparatus of claim 1, wherein:
the transistor structure is a first transistor structure;
the source and drain bodies are first source and drain bodies;
the gate electrode is a first gate electrode;
the channel region is a first channel region, comprising a first width between the first and second edges in the first transistor structure;
a semiconductor region comprises the first channel region and the first and second edges;
the semiconductor region extends beyond the first transistor structure and comprises a third channel region between third source and drain bodies in a third transistor structure, the third channel region comprising a third width between the second edge and an opposing fourth edge;
the third width is greater than the first width;
a third gate electrode is between the third source and drain bodies and over the third channel region;
a fifth metallization structure is over and in contact with a first of the third source and drain bodies;
a sixth metallization structure is over and in contact with a second of the third source and drain bodies; and
the third gate electrode and the fifth and sixth metallization structures extend in the second direction beyond the fourth edge to at least the second distance from the second edge of the semiconductor region.

7. The apparatus of claim 1, wherein:
the transistor structure is a first transistor structure of a first conductivity type;
the source and drain bodies are first source and drain bodies;
the channel region is a first channel region;
a first semiconductor region comprises the first channel region and the first and second edges;
a second semiconductor region comprises a fourth channel region and fifth and sixth edges, the fourth channel region between fourth source and drain bodies in a fourth transistor structure of a second conductivity type, the second conductivity type complementary to the first conductivity type;
the gate electrode extends between the fourth source and drain bodies and over the fourth channel region to beyond the sixth edge of the fourth channel region to a seventh distance from the fifth edge, the fifth edge adjacent the second edge and opposite the sixth edge;
seventh and eighth metallization structures extend in the second direction, the seventh metallization structure over and in contact with a first of the fourth source and drain bodies and extending to an eighth distance from the fifth edge of the fourth channel region, the eighth metallization structure over and in contact with a second of the fourth source and drain bodies and extending to a ninth distance from the fifth edge of the fourth channel region;
the eighth distance is greater than the ninth distance; and
the ninth distance is greater than the seventh distance.

8. The apparatus of claim 7, wherein:
the first semiconductor region extends beyond the first transistor structure and comprises a second channel region between second source and drain bodies in a second transistor structure of the first conductivity type;
the first channel region comprises a first width greater than a second width of the second channel region;
the second semiconductor region extends beyond the fourth transistor structure and comprises a fifth channel region between fifth source and drain bodies in a fifth transistor structure of the second conductivity type;
the fourth channel region comprises a fourth width greater than a fifth width of the fifth channel region;
a second gate electrode is over the second and fifth channel regions, between the second source and drain bodies and between the fifth source and drain bodies, the second gate electrode extending in the second direction to a fourth distance from the second edge of the second channel region and to a tenth distance from the fifth edge of the fifth channel region;
third and fourth metallization structures extend in the second direction, the third metallization structure over and in contact with a first of the second source and drain bodies, the fourth metallization structure over and in contact with a second of the second source and drain bodies and extending to a sixth distance from the second edge of the second channel region;
the fourth distance is greater than the sixth distance;
ninth and tenth metallization structures extend in the second direction, the ninth metallization structure over and in contact with a first of the fifth source and drain bodies, the tenth metallization structure over and in contact with a second of the fifth source and drain bodies and extending to an eleventh distance from the fifth edge of the fifth channel region; and
the tenth distance is greater than the eleventh distance.

9. An apparatus, comprising:
a channel region extending in a first direction between source and drain bodies in a transistor structure, wherein the source and drain bodies comprise an impurity-doped semiconductor material;
a gate electrode between the source and drain bodies and over the channel region, wherein the gate electrode extends in a second direction, orthogonal to the first direction, beyond a first edge of the channel region to a first distance from a second edge, opposite the first edge; and
first and second metallization structures extending in the second direction, wherein the first metallization structure is over and in contact with a first of the source and drain bodies and extends beyond the first edge to a second distance from the second edge of the channel region, the second metallization structure is over and in contact with a second of the source and drain bodies and extends beyond the first edge to a third distance from the second edge of the channel region, the second distance is greater than the first distance, and the first distance is greater than the third distance.

10. The apparatus of claim 9, wherein:
the transistor structure is a first transistor structure;
the source and drain bodies are first source and drain bodies;
the gate electrode is a first gate electrode;
the channel region is a first channel region;
a semiconductor region comprises the first channel region and the first and second edges;
the semiconductor region extends beyond the first transistor structure and comprises a second channel region between second source and drain bodies in a second transistor structure;
a second gate electrode is between the second source and drain bodies and over the second channel region, the second gate electrode extending in the second direction to a fourth distance from the second edge of the second channel region; and
third and fourth metallization structures extending in the second direction, wherein the third metallization structure is over and in contact with a first of the second source and drain bodies and extends to a fifth distance from the second edge of the channel region, the fourth metallization structure is over and in contact with a second of the second source and drain bodies and extends to a sixth distance from the second edge of the channel region, the fifth distance is greater than the fourth distance, and the sixth distance is greater than the fourth distance.

11. The apparatus of claim 10, wherein:
the first channel region comprises a first width between the first and second edges in the first transistor structure;
the second channel region comprises a second width between the second edge and a third edge in the second transistor structure, the third edge opposite the second edge; and
the second width is greater than the first width.

12. The apparatus of claim 11, wherein the second and fifth distances are approximately equal.

13. The apparatus of claim 10, wherein the semiconductor region comprises a plurality of nanoribbons.

14. The apparatus of claim 9, wherein:
the transistor structure is a first transistor structure of a first conductivity type;
the source and drain bodies are first source and drain bodies;
the channel region is a first channel region;
a first semiconductor region comprises the first channel region and the first and second edges;
a second semiconductor region comprises a second channel region and third and fourth edges, the second channel region between second source and drain bodies in a second transistor structure of a second conductivity type, the second conductivity type complementary to the first conductivity type;
the gate electrode extends between the second source and drain bodies and over the second channel region to beyond the fourth edge of the second channel region to a fourth distance from the third edge, the third edge adjacent the second edge and opposite the fourth edge;
third and fourth metallization structures extend in the second direction, the third metallization structure over and in contact with a first of the second source and drain bodies and extending to a fifth distance from the third edge of the second channel region, the fourth metallization structure over and in contact with a second of the second source and drain bodies and extending to a sixth distance from the third edge of the second channel region;
the fifth distance is greater than the fourth distance; and
the fourth distance is greater than the sixth distance.

15. The apparatus of claim 14, wherein:
the first semiconductor region extends beyond the first transistor structure and comprises a third channel region between third source and drain bodies in a third transistor structure of the first conductivity type;
the second semiconductor region extends beyond the second transistor structure and comprises a fourth channel region between fourth source and drain bodies in a fourth transistor structure of the second conductivity type;
the third and fourth channel regions comprise a first width greater than a second width of the first and second channel regions;
a second gate electrode is over the third and fourth channel regions, between the third source and drain bodies and between the fourth source and drain bodies, the second gate electrode extending in the second direction to a seventh distance from the second edge of the third channel region and to an eighth distance from the third edge of the fourth channel region;
fifth and sixth metallization structures extend in the second direction, the fifth metallization structure over and in contact with a first of the third source and drain bodies, the sixth metallization structure over and in contact with a second of the third source and drain bodies and extending to a ninth distance from the second edge of the third channel region;
the ninth distance is greater than the seventh distance;
seventh and eighth metallization structures extend in the second direction, the seventh metallization structure over and in contact with a first of the fourth source and drain bodies, the eighth metallization structure over and in contact with a second of the fourth source and drain bodies and extending to a tenth distance from the third edge of the fourth channel region; and
the tenth distance is greater than the eighth distance.

16. An apparatus, comprising:
a semiconductor region extending in a first direction and comprising first and second widths, the first width in a channel region between source and drain bodies in a transistor structure, one of the source and drain bodies between the first and second widths;
a gate electrode between the source and drain bodies and over the channel region, wherein the gate electrode extends in a second direction, orthogonal to the first direction, beyond an edge of the channel region to a first distance from the edge of the channel region;
a first metallization structure over and in contact with a first of the source and drain bodies and extending in the second direction to a second distance from the edge of the channel region greater than the first distance; and
a second metallization structure over and in contact with a second of the source and drain bodies and extending in the second direction to a third distance from the edge of the channel region, wherein the second distance is greater than the third distance.

17. The apparatus of claim 16, wherein:
the transistor structure is a first transistor structure;
the source and drain bodies are first source and drain bodies;
the gate electrode is a first gate electrode;
the channel region is a first channel region;
the semiconductor region comprises the edge and a second channel region with the second width between second source and drain bodies in a second transistor structure;
the second width is greater than the first width;
a second gate electrode is between the second source and drain bodies and over the second channel region; and
third and fourth metallization structures, wherein the third metallization structure is over and in contact with a first of the second source and drain bodies, the fourth metallization structure is over and in contact with a second of the second source and drain bodies, and the second gate electrode and the third and fourth metallization structures extend in the second direction to at least the second distance from the edge of the second channel region.

18. The apparatus of claim 17, wherein:
the semiconductor region comprises a third channel region with a third width between third source and drain bodies in a third transistor structure;
the first width is greater than the third width;
a third gate electrode is between the third source and drain bodies and over the third channel region, the third gate electrode extending in the second direction to a fourth distance from the edge of the second channel region;
fifth and sixth metallization structures extend in the second direction, the fifth metallization structure over and in contact with a first of the third source and drain bodies and extending to a fifth distance from the edge of the second channel region, the sixth metallization structure over and in contact with a second of the third source and drain bodies and extending to a sixth distance from the edge of the second channel region;
the third distance is greater than the first distance;
the second distance is greater than or equal to the fifth distance; and
the fourth distance is greater than the sixth distance.

19. The apparatus of claim 16, wherein:
the transistor structure is a first transistor structure;
the source and drain bodies are first source and drain bodies;
the gate electrode is a first gate electrode;
the channel region is a first channel region;
the semiconductor region comprises the edge and a second channel region with the second width between second source and drain bodies in a second transistor structure;
the first width is greater than the second width;
the third distance is greater than the first distance;
a second gate electrode is between the second source and drain bodies and over the second channel region, the second gate electrode extending in the second direction to a fourth distance from the edge of the second channel region; and
third and fourth metallization structures extend in the second direction, the third metallization structure over and in contact with a first of the second source and drain bodies and extending to a fifth distance from the edge of the second channel region, the fourth metallization structure over and in contact with a second of the second source and drain bodies and extending to a sixth distance from the edge of the second channel region;
the fifth distance is greater than the fourth distance; and
the fourth distance is greater than the sixth distance.

20. The apparatus of claim 19, wherein:
the semiconductor region is a first semiconductor structure;
the first and second transistor structures are of a first conductivity type;
a second semiconductor region comprises a second edge and third and fourth channel regions in third and fourth transistor structures of a second conductivity type, the second conductivity type complementary to the first conductivity type, the third channel region comprising the first width between third source and drain bodies, the fourth channel region comprising the second width between fourth source and drain bodies;
the first gate electrode extends between the third source and drain bodies and over the third channel region to less than the second distance from the second edge; and
the second gate electrode extends between the fourth source and drain bodies and over the fourth channel region to less than the second distance from the second edge.
